(19) United States
(12) Patent Application Publication
(10) Pub. No.: US 2017/0317250 A1
(43) Pub. Date: Nov. 2, 2017

(54) SUBSTRATE, LIGHT-EMITTING DEVICE, AND ILLUMINATING APPARATUS

(71) Applicant: Sharp Kabushiki Kaisha, Sakai City, Osaka (JP)

(72) Inventors: Masahiro KONISHI, Sakai City (JP); Shin ITOH, Sakai City (JP); Hiroshi YAMASHITA, Sakai City (JP); Hiroyuki NOKUBO, Sakai City (JP); Yoshiaki ITAKURA, Sakai City (JP)

(21) Appl. No.: 15/520,169

(22) PCT Filed: Sep. 25, 2015
(86) PCT No.: PCT/JP2015/077042

§ 371 Date: Apr. 19, 2017

(30) Foreign Application Priority Data
Oct. 28, 2014 (JP) 2014-219616

(51) Int. Cl. H01L 33/60; H01L 33/52

(52) U.S. Cl. CPC H01L 33/60; H01L 33/52

(57) ABSTRACT

Provided is a substrate having dielectric strength and light reflectivity, as well as excellent mass productivity. A substrate (10) for mounting a light-emitting element (20) thereon includes a base (12) and an insulation layer (30) disposed directly or indirectly on a surface of the base (12). The insulation layer (30) includes a reflection layer (32) that reflects light and a mesh glass sheet 31 that is disposed within the reflection layer (32) and that has a coefficient of linear expansion smaller than that of the reflection layer (32).

### TECHNICAL FIELD

The present invention relates to light-emitting-device substrates and light-emitting devices using such light-emitting-device substrates. In particular, the present invention relates to a light-emitting-device substrate having both high dielectric strength and high heat dissipation.

### BACKGROUND ART

A light-emitting-device substrate basically needs to have the following capabilities: high reflectivity, high heat dissipation, dielectric strength, and long-term reliability. In particular, a light-emitting-device substrate used for high-intensity illumination needs to have high dielectric strength.

A known light-emitting device in the related art includes, as a light-emitting-device substrate, a ceramic substrate or a substrate provided with an organic resist layer as an insulation layer on a metallic base. The following description mainly focuses on the problems in ceramic substrates and substrates using metallic bases.

(Ceramic Substrate)

For example, a ceramic substrate is fabricated by forming an electrode pattern on a plate-shaped ceramic base. With the tendency of higher output of light-emitting devices, a large number of light-emitting elements are arranged on a substrate to increase the brightness. As a result, ceramic substrates are becoming larger in size over the years.

In detail, in a case where a common LED (light-emitting diode) light-emitting device used at an input power of 30 W is realized by arranging face-up-type blue LED elements (in which the active layer is located away from the mounting surface) with a size of about 650 μm by 650 μm or with a similar size on a mid-size single substrate, about 100 blue LED elements are necessary. An example of a ceramic substrate having this number of LED elements arranged thereon has a planar size of 20 mm by 20 mm or larger and a thickness of about 1 mm.

In a case where an even brighter LED-illumination light-emitting device with an input power of 100 W or higher is to be realized, 400 or more blue LED elements can all be mounted at once as a consequence of technical development based on such an increase in size of substrates. A larger-size ceramic substrate with a planar size of at least 40 mm by 40 mm is necessary.

However, even if ceramic substrates are to be increased in size to realize them on a commercial basis based on such demands for increasing the size of ceramic substrates, it is difficult to realize them on a commercial basis due to three problems, which are the strength, manufacturing precision, and manufacturing cost of ceramic substrates.

In detail, since a ceramic material is basically pottery, there is a problem in terms of the strength of a ceramic substrate when increased in size. If the substrate is increased in thickness to overcome this problem, new problems occur, such as an increase in the material cost of the ceramic substrate as well as increased thermal resistance (poor heat dissipation). Moreover, when the ceramic substrate is increased in size, not only the outer dimensions of the ceramic substrate but also the dimensions of the electrode pattern to be formed on the ceramic substrate tend to go out of order. As a result, this is problematic in that the manufacturing cost of ceramic substrates tends to increase due to reduced yield rate of ceramic substrates.

In addition to such problems occurring with the increase in size of ceramic substrates, there is also a problem regarding an increase in the number of light-emitting elements mounted on a ceramic substrate. For example, in the aforementioned light-emitting device, an extremely large number of light-emitting elements, namely, 400 or more, are mounted on a single ceramic substrate, which is one of the factors for causing the reduction of the yield rate.

Furthermore, with regard to face-up-type light-emitting elements, since the active layer is located away from the light-emitting-element mounting surface of the light-emitting-device substrate, the thermal resistance to the active layer is high, and the light-emitting elements are affected by a die bonding paste used for fixing the light-emitting elements to the substrate, causing the temperature of the active layer to readily increase. In a high-output light-emitting device having a large number of light-emitting elements mounted on a single ceramic substrate, the basic substrate temperature is high, and the temperature of the active layer of each light-emitting element is even higher with the addition of the substrate temperature, obviously reducing the lifespan of the light-emitting elements.

(Substrate Using Metallic Base)

For overcoming the aforementioned problems in such ceramic substrates, a metallic base with high thermal conductivity is sometimes used as a high-output-light-emitting-device substrate. In order to mount light-emitting elements on the metallic base, an insulation layer has to be provided on the metallic base for forming an electrode pattern for connecting to the light-emitting elements.

One example of an insulation layer conventionally used in a light-emitting-device substrate is an organic resist.

In order to improve the light utilization efficiency in a high-output-light-emitting-device substrate, the aforementioned insulation layer needs to have high light reflectivity.

However, in the case where an organic resist conventionally used as an insulation layer in a light-emitting-device substrate is to be used, sufficient thermal conductivity and sufficient heat and light resisting properties are not obtainable, and dielectric strength required in a high-output-light-emitting-device substrate is not obtainable. Furthermore, in order to improve the light utilization efficiency, it is necessary to reflect light leaking toward the metallic base via the insulation layer. However, in the configuration using the conventional organic resist as the insulation layer, sufficient light reflectivity is not obtainable.

There has been proposed a substrate on which an insulation layer is formed by using a ceramic-based coating on a substrate that uses a metallic base.

With such a light-emitting-device substrate having a light-reflection-and-insulation layer formed thereon by using a ceramic-based coating on the surface of the metallic base, a light-emitting-device substrate with good reflectivity and good heat and light resisting properties can be realized. Patent Literature 1 discloses a method of forming a light-reflection-and-insulation layer by applying a ceramic-based coating onto a base.

Furthermore, Patent Literature 4 discloses forming a ceramic layer by performing an aerosol deposition method (sometimes referred to as “AD method” hereinafter) on the surface of a metallic substrate.

Furthermore, Patent Literature 5 discloses a technique of manufacturing a light-source substrate without using a coating by, for example, forming an insulation layer composed of a ceramic material, such as alumina, on a metallic base, which is a base, by plasma spraying. With such a light-source substrate having an alumina insulation layer formed thereon by plasma spraying, a good light-source substrate with excellent dielectric strength can be realized.

### CITATION LIST

### Patent Literature

PTL 1: Japanese Unexamined Patent Application Publication No. 59-149958 (Aug. 28, 1984)

PTL 2: Japanese Unexamined Patent Application Publication No. 2012-102007 (May 31, 2012)

PTL 3: Japanese Unexamined Patent Application Publication No. 2012-69749 (Apr. 5, 2012)

PTL 4: Japanese Unexamined Patent Application Publication No. 2006-332382 (Dec. 7, 2006)

PTL 5: Japanese Unexamined Patent Application Publication No. 2007-317701 (Dec. 6, 2007)

### SUMMARY OF INVENTION

### Technical Problem

However, the light-emitting-device substrate having the light-reflection-and-insulation layer formed on the surface of the metallic base by using the ceramic-based coating serving as a resin or glass binder is problematic in that it has low dielectric strength, even though it has excellent reflectivity and heat dissipation. For example, in a case where a bright LED-illumination light-emitting device with an input power of 100 W or higher is to be realized by using the aforementioned substrate, it is not possible to ensure high dielectric strength required in a light-emitting-device substrate intended for high-intensity illumination, unlike a ceramic substrate.

In contrast, in the case of the light-emitting-device substrate having the light-reflection-and-insulation layer formed on the surface of the metallic base by using the ceramic-based coating, if the required high dielectric strength is to be stably ensured by increasing the thickness of the light-reflection-and-insulation layer so as to ensure sufficient dielectric strength, a problem occurs in terms of reduced heat dissipation due to increased thermal resistance.

This is due to the generally-low thermal conductivity of the ceramic-based coating for forming the light reflection layer. In order to realize high reflectivity with a small layer thickness, the ceramic particles to be used normally tends to have high reflectivity and low thermal conductivity. Furthermore, since a low-thermal-conductivity material, such as resin or glass, is required as a binder, it is difficult to achieve both dielectric strength and heat dissipation with the ceramic-based coating alone.

With the light-emission substrate having the alumina insulation layer formed by the AD method disclosed in Patent Literature 4 or the light-emitting-device substrate having the alumina insulation layer formed by plasma spraying disclosed in Patent Literature 5, a light-emitting-device substrate with excellent dielectric strength and good heat dissipation is formed.

A layer composed of alumina alone and formed by plasma spraying or the AD method has a reflectivity of 85% at maximum and thus has good light reflectivity, but a reflectivity that exceeds 90% to 95% used in high-intensity illumination is not obtainable. Therefore, as a light-emitting-device substrate used in high-intensity illumination that requires a reflectivity of 90% or higher or even 95% or higher, there is a problem in that the reflectivity is low.

Accordingly, with regard to conventional light-emitting-device substrates using metallic bases, substrates that have low thermal resistance, excellent heat dissipation, excellent dielectric strength, and high light reflectivity do not exist at least in a form suitable for mass production.

This is a common problem in light-emitting-device substrates using metallic bases, regardless of a case where a face-up-type light-emitting element having the active layer disposed at the upper side of the light-emitting element is used or a case where a flip-chip-type light-emitting element having the active layer disposed at the lower side of the light-emitting element is used.

In order to overcome such a problem, for example, a flip-chip-type light-emitting-element substrate having the following structure has been attempted.

Specifically, the substrate includes a metallic base, a second insulation layer having thermal conductivity, a wiring pattern formed on the second insulation layer, and a first insulation layer having light reflectivity and formed on the second insulation layer and on a section of the wiring pattern such that the remaining section of the wiring pattern is exposed. Moreover, the thermal conductivity of the second insulation layer is higher than that of the first insulation layer, and the light reflectivity of the first insulation layer is higher than that of the second insulation layer. It is conceived that, with this structure, there is a high possibility of realizing a substrate having low thermal resistance, excellent heat dissipation, excellent dielectric strength, and high light reflectivity.

The second insulation layer may be a resin sheet or glass layer containing an inorganic solid material having high thermal conductivity typified by ceramic particles, such as alumina or aluminum nitride, or may be an insulation layer formed by depositing a ceramic layer by spraying ceramic particles at high speed toward a metallic base in accordance with, for example, the spraying or AD method (aerosol deposition method). The first insulation layer may be a resin or glass layer containing an inorganic solid material having high light reflectivity typified by ceramic particles, such as titanium oxide, alumina, or zirconia.

In a light-emitting device using the above-described light-emitting-device substrate, the light-emitting elements mounted on the light-emitting-device substrate are normally covered by sealing resin. This is used not only for protecting the light-emitting elements, the light reflection surface, the electrodes, and so on, but also for toning the color of emitted light by mixing fluorescent particles with the sealing resin.

In this case, the following problem occurs. When thermal expansion and contraction occur in the light-emitting device, the first insulation layer having light reflectivity may sometimes delaminate together with the sealing resin from the under layer. Normally, when the first insulation layer having light reflectivity has a thickness of about 50 μm, sufficient reflectivity is obtained. In contrast, the sealing resin is normally ten or more times thicker at about 0.5 mm to 1 mm. In a case where the adhesion strength between the sealing resin and the first insulation layer is greater than the adhesion strength of the first insulation layer relative to the second insulation layer and the wiring pattern, and the coefficient of linear expansion of the sealing resin is larger than that of the second insulation layer or the wiring pattern, it is conceivable that the first insulation layer may delaminate from the under layer by being pulled by the movement of the sealing resin, which has a large volume.

The same problem exists in light-emitting-device substrates formed for face-up-type light-emitting elements.

Specifically, this corresponds to the case of a light-emitting-device substrate that includes a metallic base, a second insulation layer having thermal conductivity, a first insulation layer having light reflectivity and formed on the second insulation layer, and a wiring pattern formed on the first insulation layer, and in which the thermal conductivity of the second insulation layer is higher than that of the first insulation layer and the light reflectivity of the first insulation layer is higher than that of the second insulation layer, such that the light-emitting-device substrate has low thermal resistance, excellent heat dissipation, excellent dielectric strength, and high light reflectivity.

Even with this example, in a light-emitting device in which the light-emitting elements disposed on the light-emitting-device substrate are sealed by resin, the thermal expansion and contraction may sometimes cause the first insulation layer adhered to the sealing resin to delaminate from the second insulation layer.

The present invention has been made in view of the aforementioned problems in the related art, and an object thereof is to provide a substrate for disposing a light-emitting element thereon and having dielectric strength and light reflectivity as well as being highly mass productive, and also to provide a light-emitting device using the substrate.

### Solution to Problem

In order to solve the aforementioned problems, a substrate according to an aspect of the present invention is for mounting a light-emitting element thereon and includes a base and a first insulation layer disposed directly or indirectly on a surface of the base. The first insulation layer includes a resin layer that reflects light and a mesh structural member that is disposed within the resin layer and that has a coefficient of linear expansion smaller than that of the resin layer.

In order to solve the aforementioned problems, a light-emitting device according to an aspect of the present invention includes a substrate, a light-emitting element mounted on the substrate, and sealing resin that covers the light-emitting element. The substrate includes a base and a first insulation layer disposed directly or indirectly on a surface of the base. The first insulation layer includes a resin layer that reflects light and a mesh structural member that is disposed within the resin layer and that has a coefficient of linear expansion smaller than that of the sealing resin.

### Advantageous Effects of Invention

An aspect of the present invention is advantageous in being able to provide a substrate for disposing a light-emitting element thereon and having dielectric strength and light reflectivity as well as being highly mass productive.

### BRIEF DESCRIPTION OF DRAWINGS

FIG. 1 is a cross-sectional view taken along a plane AA shown in FIG. 2.

FIG. 2 is a plan view illustrating the configuration of a light-emitting device according to a first embodiment.

FIG. 3 includes a perspective view (a) illustrating the external appearance of an illuminating apparatus according to the first embodiment and a cross-sectional view (b) of the illuminating apparatus.

FIG. 4 is a perspective view illustrating the external appearance of the light-emitting device and a heatsink according to the first embodiment.

FIG. 5 is a cross-sectional view for explaining a manufacturing method of a substrate according to the first embodiment.

FIG. 6 is a cross-sectional view for explaining the manufacturing method of the substrate according to the first embodiment.

FIG. 7 is a cross-sectional view for explaining the manufacturing method of the substrate according to the first embodiment.

FIG. 8 is a cross-sectional view for explaining the manufacturing method of the substrate according to the first embodiment.

FIG. 9 is a cross-sectional view for explaining the manufacturing method of the substrate according to the first embodiment.

FIG. 10 is a cross-sectional view for explaining the manufacturing method of the substrate according to the first embodiment.

FIG. 11 is a cross-sectional view illustrating the configuration of a light-emitting device according to a modification of the first embodiment.

FIG. 12 includes a plan view (a) illustrating the configuration of a light-emitting device according to a second embodiment and a cross-sectional view (b) taken along a plane BB shown in (a).

FIG. 13 includes a plan view (a) illustrating the configuration of a substrate provided in the light-emitting device, a cross-sectional view (b) taken along a plane CC shown in (a), and a partially enlarged view (c) of the cross-sectional view.

FIG. 14 is a cross-sectional view for explaining a manufacturing method of the substrate according to the second embodiment.

FIG. 15 is a cross-sectional view for explaining the manufacturing method of the substrate according to the second embodiment.

FIG. 16 is a cross-sectional view for explaining the manufacturing method of the substrate according to the second embodiment.

FIG. 17 is a cross-sectional view for explaining the manufacturing method of the substrate according to the second embodiment.

FIG. 18 is a schematic cross-sectional view of a substrate according to a comparative example with respect to the second embodiment.

FIG. 19 includes a plan view (a) illustrating the configuration of a substrate according to a third embodiment, a cross-sectional view (b) taken along a plane DD shown in (a), and a partially enlarged view (c) of the cross-sectional view.

### DESCRIPTION OF EMBODIMENTS

### First Embodiment

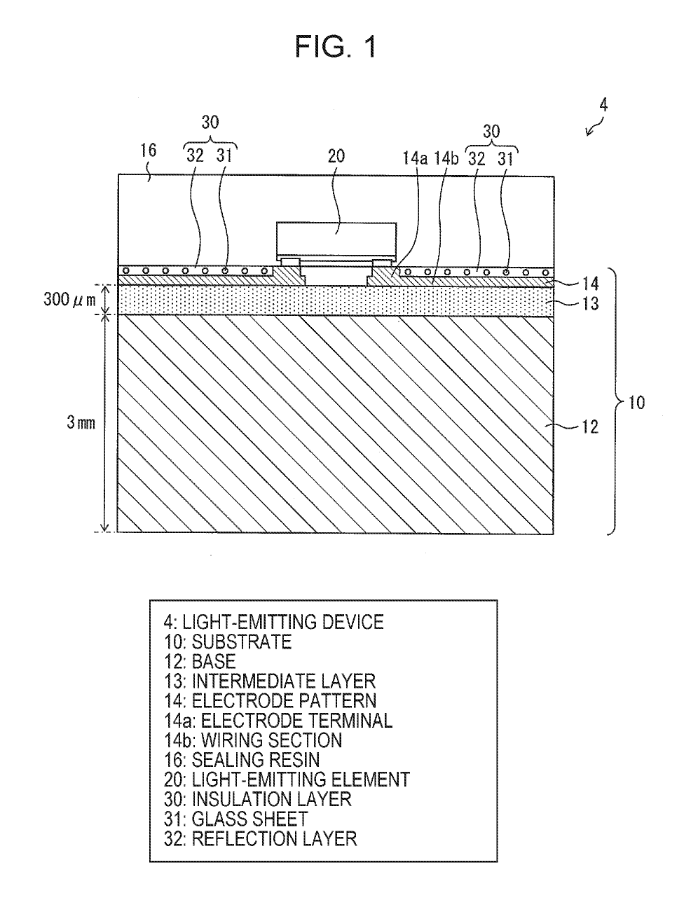

A first embodiment of the present invention will be described below with reference to FIGS. 1 to 11.

(Configuration of Illuminating Apparatus 1)

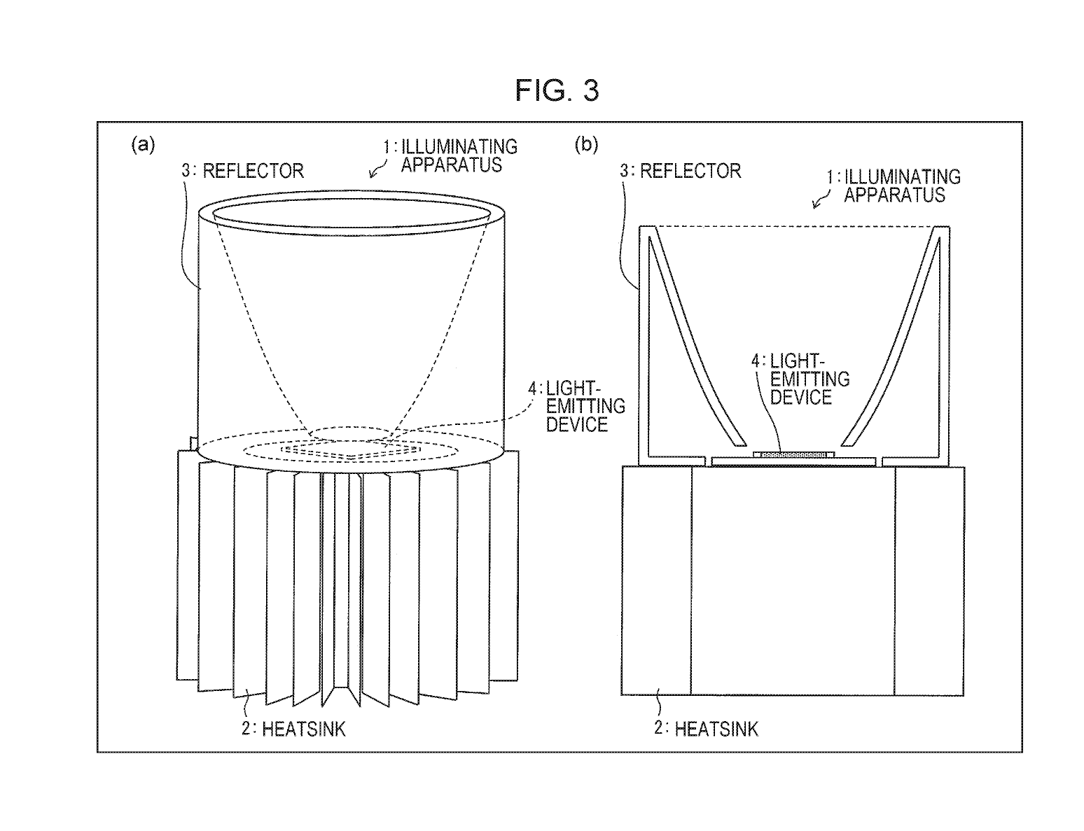

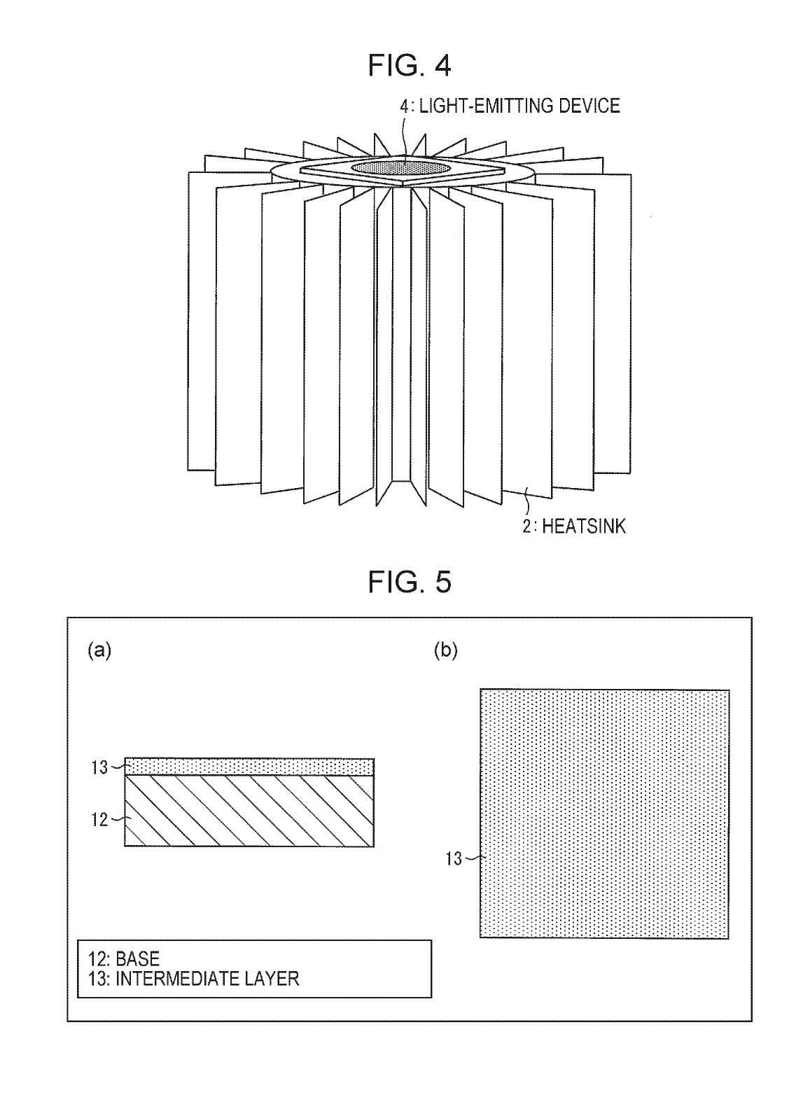

First, the configuration of an illuminating apparatus 1 in which a light-emitting device 4 according to this embodiment is used will be described with reference to FIGS. 3 and 4. FIG. 3 includes a perspective view (a) illustrating the external appearance of the illuminating apparatus 1 according to the first embodiment and a cross-sectional view (b) of the illuminating apparatus 1. The illuminating apparatus 1 includes the light-emitting device 4, a heatsink 2 for dissipating heat generated from the light-emitting device 4, and a reflector 3 that reflects light output from the light-emitting device 4. The light-emitting device 4 may be used by being attached to the heatsink 2. FIG. 4 is a perspective view illustrating the external appearance of the light-emitting device 4 and the heatsink 2 according to the first embodiment. FIG. 4 illustrates an example in which the light-emitting device 4 is disposed in the heatsink 2.

As shown in FIGS. 3 and 4, the heatsink 2 includes a cylindrical core and a plurality of plate-like members arranged on the surface of the core. In plan view, the heatsink 2 is configured such that the plurality of plate-like members extend radially from the core disposed at the center. With the plurality of plate-like members arranged in this manner, the heatsink 2 has high heat dissipation efficiency with respect to the heat generated from the light-emitting device 4.

The reflector 3 is disposed on the upper surface (i.e., the surface at the top of the head of the core) serving as one surface of the heatsink 2. The reflector 3 has an inner side surface that is bent so as to form a part of a parabola in cross section. The light-emitting device 4 is disposed at the bottom surface inside the reflector 3. Thus, the light emitted from the light-emitting device 4 is reflected at the inner side surface of the reflector 3 and is output efficiently from the reflector 3 in the output direction. Furthermore, the heat generated from the light-emitting device 4 is transferred to the plurality of plate-like members of the heatsink 2 and is dissipated from the plurality of plate-like members.

(Configuration of Light-Emitting Device 4)

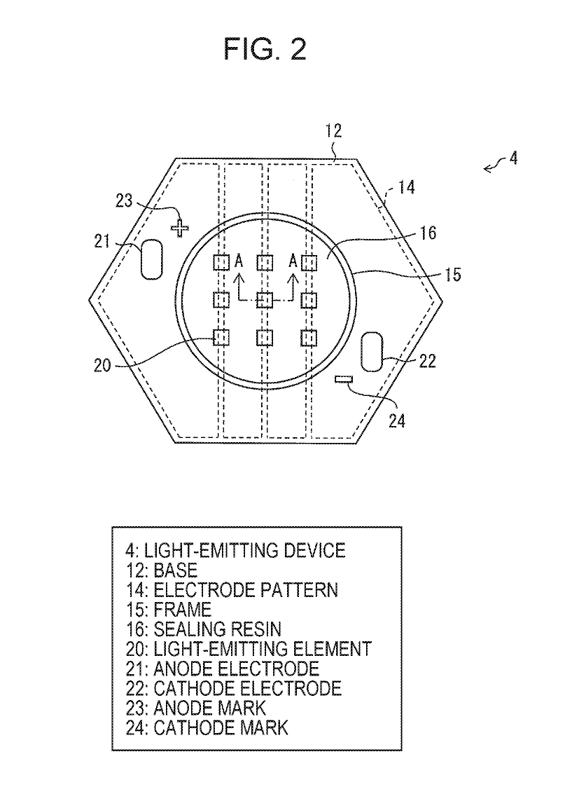

Next, the configuration of the light-emitting device 4 will be described with reference to FIGS. 1 and 2. FIG. 2 is a plan view illustrating the configuration of the light-emitting device 4 according to the first embodiment. FIG. 1 is a cross-sectional view taken along a plane AA shown in FIG. 2.

As shown in FIGS. 1 and 2, the light-emitting device 4 includes a substrate 10, light-emitting elements 20, and sealing resin 16 that seals the light-emitting elements 20. The substrate 10 includes a base 12, an intermediate layer (second insulation layer) 13, an electrode pattern (wiring pattern) 14, and an insulation layer (first insulation layer) 30. In this embodiment, the insulation layer 30 has a glass sheet (structural member) 31, which is a mesh-woven structural member, and also has a white reflection layer (resin layer) 32 that covers the glass sheet 31. The electrode pattern 14 includes a plurality of electrode terminals 14a for connecting to the light-emitting elements 20 and a wiring section 14b that at least connects between the plurality of electrode terminals 14a.

The light-emitting elements 20 are connected to the electrode terminals 14a so as to be electrically connected to the electrode pattern 14. In FIG. 2, nine light-emitting elements (LED chips) 20 arranged in three rows by three columns are illustrated. The nine light-emitting elements 20 have a connection configuration (i.e., a three-series three-parallel connection configuration) such that the nine light-emitting elements 20 are parallel-connected in three rows by the electrode pattern 14 and that the three rows respectively have three series circuits of light-emitting elements 20. Needless to say, the number of light-emitting elements 20 is not limited to nine, and the light-emitting elements 20 do not need to have a three-series three-parallel connection configuration.

Furthermore, the light-emitting device 4 includes a frame 15, an anode electrode (anode land or anode connector) 21, a cathode electrode (cathode land or cathode connector) 22, an anode mark 23, and a cathode mark 24.

The frame 15 functions as a resin dam for damming the sealing resin 16, and is a ring-shaped (arch-shaped) frame provided on the electrode pattern 14 and the insulation layer 30 and composed of alumina-filler-containing silicone resin. The material of the frame 15 is not limited to this and may be any type of insulating resin having light reflectivity. Moreover, the shape is not limited to the ring-shape (arch-shape) and may be a freely-chosen shape.

The sealing resin 16 is a sealing resin layer composed of light transmissive resin. The sealing resin 16 fills a region surrounded by the frame 15 so as to seal the light-emitting elements 20 and the insulation layer 30. Furthermore, the sealing resin 16 contains a fluorescent material. The fluorescent material used is a fluorescent material that is excited by first-order light released from the light-emitting elements 20 and that releases light with a wavelength longer than that of the first-order light.

The fluorescent material contained in the sealing resin 16 is not particularly limited and may be appropriately selected in accordance with, for example, the desired white-color chromaticity. Examples of a combination of a daylight white color and a warm white color that can be used include a combination of a YAG yellow fluorescent material and a (Sr, Ca)AlSiN₃:Eu red fluorescent material and a combination of a YAG yellow fluorescent material and a CaAlSiN₃:Eu red fluorescent material. An example of a combination of high rendering colors that can be used includes a combination of a (Sr, Ca)AlSiN₃ :Eu red fluorescent material and a Ca₃(Sc, Mg)₂Si₃O₁₂:Ce green fluorescent material or a Lu₃Al₅O₁:Ce green fluorescent material. Alternatively, a combination of other fluorescent materials may be used, or a configuration including a YAG yellow fluorescent material alone as a pseudo white color may be used.

The anode electrode 21 and the cathode electrode 22 are electrodes that feed electric current to the light-emitting elements 20 for driving the light-emitting elements 20 and are provided in the form of lands. The anode electrode 21 and the cathode electrode 22 may be provided in the form of connectors by setting the connectors in the lands. The anode electrode 21 and the cathode electrode 22 are electrodes that are connectable to an external power source (not shown) in the light-emitting device 4. The anode electrode 21 and the cathode electrode 22 are connected to the light-emitting elements 20 via the electrode pattern 14.

The anode mark 23 and the cathode mark 24 are reference alignment marks for positioning the anode electrode 21 and the cathode electrode 22, respectively. Furthermore, the anode mark 23 and the cathode mark 24 have functions for indicating the polarities of the anode electrode 21 and the cathode electrode 22, respectively.

The thickness of sections of the electrode pattern 14 that are directly below the anode electrode 21 and the cathode electrode 22 is larger than the thickness of a section (corresponding to the wiring section 14b, which is a section covered by the insulation layer 30, in the electrode pattern 14 in FIG. 1) of the electrode pattern 14 located at a position other than the directly-below sections.

Specifically, the thickness of the electrode pattern 14 is preferably between 70 μm and 300 μm inclusive directly below the anode electrode 21 and the cathode electrode 22 and between 35 μm and 250 μm inclusive at the position other than the directly-below sections. While the heat dissipation function of the light-emitting device 4 becomes higher as the electrode pattern 14, particularly, the wiring section 14b, is increased in thickness, even in a case where the thickness of the electrode pattern 14 exceeds 300 μm such that the electrode pattern 14 or the wiring section 14b is made thicker than this, the heat resistance decreases and the heat dissipation improves by keeping a sufficient distance between the light-emitting elements 20. For example, by setting the distance between the light-emitting elements 20 to 600 μm or larger, which is two or more times the thickness of 300 μm of the electrode pattern 14, the heat resistance can be reduced. Although the heat dissipation improves by keeping a sufficient distance between the light-emitting elements in this manner, the number of mountable light-emitting elements per light-emitting-device substrate decreases. As a practical marginal limit, the thickness of the electrode pattern 14 is 300 μm or smaller directly below the anode electrode 21 and the cathode electrode 22 and 250 μm or smaller at other positions, but is not limited thereto depending on the purpose or the intended use.

It is preferable that the total bottom surface area of the electrode pattern 14 be at least four times the total area of the electrode terminals of the electrode pattern 14 to which the light-emitting elements 20 are to be mounted. Because the thermal conductivity of the intermediate layer 13 shown in FIG. 1 is lower than the thermal conductivity of the electrode pattern 14, if the area of the section of the electrode pattern 14 that is in contact with the intermediate layer 13 is sufficiently large, the heat resistance received by the heat passing through the intermediate layer 13 can be reduced. Although the rate of the aforementioned area is set at four times or larger assuming that the thermal conductivity of the intermediate layer 13 is 15 W/(m·° C.), if the thermal conductivity of the intermediate layer 13 is lower than this at, for example, 7.5 W/(m·° C.), it is desirable that the rate of the aforementioned area be set at eight times or larger. It is desirable that the total bottom surface area of the electrode pattern 14 be as large as possible as the thermal conductivity of the intermediate layer 13 decreases.

Furthermore, as shown in FIG. 2, although the outline of the base 12 in the base surface direction is hexagonal as an example, the outline of the base 12 is not limited to this shape, and a freely-chosen closed shape may be employed. Moreover, the perimeter of the closed shape may be constituted of straight lines alone or a curve alone, or may include at least one straight line and at least one curve. Furthermore, the closed shape is not limited to a convex shape and may alternatively be a concave shape. For example, a triangular shape, a rectangular shape, a pentagonal shape, or an octagonal shape may be employed as an example of a convex polygonal shape constituted of straight lines alone, or a freely-chosen concave polygonal shape may be employed. Moreover, as an example of a closed shape constituted of a curve alone, a circular shape or an elliptical shape may be employed, or a closed shape such as a convex curve shape or a concave curve shape may be employed. Furthermore, as an example of a closed shape including at least one straight line and at least one curve, a racetrack-like shape may be employed.

(Configuration of Substrate 10)

The layers provided in the substrate 10 will be described below with reference to FIG. 1. As shown in FIG. 1, the substrate 10 includes the base 12 composed of a metallic material, the intermediate layer 13 having thermal conductivity and formed on one surface of the base 12, the electrode pattern 14 formed on the intermediate layer 13, and the insulation layer 30 having light reflectivity and formed on the intermediate layer 13 and the wiring section 14b, which is one section of the electrode pattern 14, such that the electrode terminals 14a, which are other sections of the electrode pattern 14, are exposed.

[Base 12 Composed of Metallic Material]

In the first embodiment, an aluminum base is used as the base 12 composed of a metallic material. An example of an aluminum base that can be used is an aluminum plate with a vertical side of 50 mm, a horizontal side of 50 mm, and a thickness of 3 mm. Advantages of using aluminum for the base 12 include lightness in weight, good machinability, and high thermal conductivity. Furthermore, the aluminum base may contain a component other than aluminum to an extent that does not interfere with an anodic oxidation process. Although this will be described in detail later, because the intermediate layer 13, the electrode pattern 14, and the insulation layer 30 having light reflectivity can be formed on the base 12 at a relatively low temperature in the first embodiment, an aluminum base, which is low-melting-point metal having a melting point of 660° C., can be used as the base 12 composed of a metallic material. Due to this reason, the base is not limited to an aluminum base and may be, for example, a copper base, a stainless steel base, or a base composed of metal containing iron as a material. Thus, there are many options for the material that can be used as the base 12 composed of a metallic material.

[Intermediate Layer 13 Having Thermal Conductivity]

In this embodiment, as shown in FIG. 1, in order to stably give high heat dissipation and high dielectric strength to the (light-emitting-device) substrate 10, the intermediate layer 13, which is a thermally-conductive ceramic insulator, is formed between the base 12 composed of a metallic material and the electrode pattern 14 or the insulation layer 30 having light reflectivity.

The intermediate layer 13 is formed by ejecting ceramic particles at high speed onto the base 12 composed of a metallic material so as to deposit the ceramic particles thereon, and is an insulation layer having good thermal conductivity. Examples of such a method include spraying, as typified by plasma spraying and high-speed frame spraying, and an AD method (aerosol deposition method).

Another method for forming the intermediate layer 13 involves forming an insulation layer having good thermal conductivity and formed of ceramic particles by using a glass or resinous binder. Specifically, the intermediate layer 13 may be formed by applying a coating containing ceramic particles onto the base 12 composed of a metallic material and then causing glass or resin to cure, or may be formed by bonding resin containing ceramic particles and molded into the shape of a sheet to the base 12 composed of a metallic material and then causing the resin to cure.

As described above, in the first embodiment, an aluminum base, which is low-melting-point metal having a melting point of 660° C., is used as the base 12 composed of a metallic material. Therefore, it is not possible to form the intermediate layer 13 by directly sintering a ceramic sintered body on the aluminum base. However, it is possible to form the intermediate layer 13 composed of a ceramic material by using the spraying or AD method on the aluminum base.

The intermediate layer 13 composed of a ceramic material may be formed by using a glass or resinous binder.

Accordingly, because a good intermediate layer 13 having high heat dissipation and high dielectric strength can be formed on the (light-emitting-device) substrate 10, high heat dissipation and high dielectric strength can be stably given to the substrate 10.

The ceramic material used for forming the intermediate layer 13 is desirably alumina due to having a good balance between high insulation and high thermal conductivity. Thus, alumina is used in the first embodiment, although not limited thereto. As an alternative to alumina, aluminum nitride and silicon nitride are preferable since they both have good thermal conductivity and good dielectric strength.

Furthermore, silicon carbide has high thermal conductivity, and zirconia and titanium oxide have high dielectric strength. Therefore, it is preferable that these materials be appropriately selected and used in accordance with the purpose or the intended use of the intermediate layer 13.

The ceramic material mentioned here is not limited to metal oxide and includes a broad range of ceramic materials, that is, general inorganic solid materials, including aluminum nitride, silicon nitride, and silicon carbide. A freely-chosen material may be selected from these inorganic solid materials so long as the material is stable, has excellent heat resisting properties, excellent thermal conductivity, and excellent dielectric strength.

Furthermore, it is desirable that the intermediate layer 13 have higher thermal conductivity than the insulation layer 30, which will be described in detail later. Therefore, it is desirable that ceramic particles having higher thermal conductivity than the insulation layer 30 be used in the intermediate layer 13.

Although the intermediate layer 13 and the insulation layer 30, which will be described later, are both insulation layers, the insulation layer 30 having light reflectivity simply has to have enough thickness for ensuring a light reflecting function. Although dependent on the ceramic material to be mixed and the amount thereof, the reflectivity of the insulation layer 30 having light reflectivity saturates when the layer thickness is substantially between 10 μm and 100 μm. Although the dielectric strength of the intermediate layer 13 also depends on the conditions for forming the insulation layer, the intermediate layer 13 is preferably formed to have a layer thickness between 50 μm and 1000 μm inclusive, and the insulation layer 30 is preferably formed to have a layer thickness between 10 μm and 300 μm inclusive. Moreover, it is desirable that the thickness of the insulation layer 30 be smaller than the thickness of the intermediate layer 13.

In particular, the intermediate layer 13 is preferably formed to have a thickness between 50 μm and 500 μm. For example, if the intermediate layer 13 can be formed to have a thickness of 100 μm, a dielectric strength of at least 1.5 kV to 3 kV can be ensured with the intermediate layer 13 alone. If the intermediate layer 13 can be formed to have a thickness of 500 μm, a dielectric strength of at least 7.5 kV to 15 kV can be ensured with the intermediate layer 13 alone.

Since the electrode pattern 14 is directly formed on the intermediate layer 13, it is demanded that the layer thickness of the intermediate layer 13 be designed such that the dielectric strength between the base 12 and the electrode pattern 14 is between about 4 kV and 5 kV. If the intermediate layer 13 has a thickness of at least 300 μm, a dielectric strength of 4.5 kV can be realized.

The thermal conductivity of a ceramic layer (intermediate layer 13) formed by using the spraying or AD method is close to the thermal conductivity of a ceramic layer formed by sintering and is, for example, a value of 10 to 30 W/(m·° C.). However, an insulation layer formed by binding ceramic particles by using a glass or resinous binder normally has a thermal conductivity of about 1 to 3 W/(m·° C.) or about 5 W/(m·° C.) at maximum due to being affected by the low thermal conductivity of the glass or resin. Accordingly, the thermal conductivity of a ceramic layer (intermediate layer 13) formed by using the spraying or AD method is higher than the thermal conductivity of an insulation layer formed by binding ceramic particles by using a glass or resinous binder.

The intermediate layer 13 may further include a plurality of layers therein, as appropriate.

[Electrode Pattern 14]

The electrode pattern 14 formed on the intermediate layer 13 can be formed by using an electrode-pattern forming method in the related art. Specifically, the electrode pattern is constituted of an electrode-foundation metallic paste and a plating layer. An example of the electrode-foundation metallic paste that can be used is a paste containing an organic material, such as resin, as a binder. By printing and drying the metallic paste and then performing a plating process, for example, an electrode pattern formed of a thick copper film can be formed.

In the first embodiment, a conductive layer formed of a thick copper film is formed on the intermediate layer 13 by plasma spraying, and the electrode pattern 14 is formed by etching.

As shown in FIG. 1, since a copper conductive layer is formed directly on the intermediate layer 13 by plasma spraying in the substrate 10, there is good adhesiveness between the intermediate layer 13 and the electrode pattern 14. Unlike the case of using the electrode-foundation metallic paste containing the organic material, such as resin, as the binder, a high resistance layer with low thermal conductivity is not interposed between the intermediate layer 13 and the electrode pattern 14, so that a substrate 10 having good heat dissipation can be realized.

Although it is effective to increase the layer thickness of the electrode pattern 14 having high thermal conductivity, especially, the wiring section 14b, to enhance the heat dissipation of the substrate 10, a thick conductive layer can be readily formed by using plasma spraying.

After the conductive layer is formed, the electrode pattern 14 is ultimately formed by cutting out the conductive layer by using etching. In the case of the thick copper conductive layer, etching can be readily performed by using ferric chloride. In spraying, protrusions and recesses are likely to form on the surface of the conductive layer. Therefore, when cutting out the electrode pattern 14 by using etching, a preliminary planarization treatment by, for example, grinding is often necessary.

The conductive layer, which is to become the electrode pattern 14, may be formed by using a spraying method other than plasma spraying, such as high-speed frame spraying or cold spraying. Spraying may be replaced with the AD method. Moreover, an electrode forming method using sputtering may be performed. However, the sputtering method has lower material utilization efficiency than in spraying and also requires high vacuum, which is problematic in terms of higher manufacturing cost.

Furthermore, in a case where the intermediate layer 13 is formed by causing resin molded into the shape of a sheet and containing ceramic particles to cure, a copper foil may be used as the thick conductive layer. For example, by bonding the resin molded into the shape of a sheet and containing ceramic particles between a copper foil with a thickness of 100 μm and the base 12 and causing the resin to cure, a three-layer-structured base having the base 12, the intermediate layer 13 formed of the resin containing the ceramic particles, and the thick conductive layer formed of 100-μm-thick copper can be prepared. The electrode pattern 14 can be cut out from the thick copper conductive layer by etching using ferric chloride.

With this method, not only the adhesiveness between the intermediate layer 13 and the electrode pattern 14 is improved, but an electrode-foundation metallic paste does not have to be used. Thus, a high resistance layer with low thermal conductivity does not have to be interposed between the intermediate layer 13 and the electrode pattern 14, whereby a substrate 10 having good heat dissipation can be realized.

Accordingly, in order to form a conductive layer for the electrode pattern 14, a method suitable for the intermediate layer 13 may be appropriately selected.

Although copper is used as the conductive layer for forming the electrode pattern 14 in the first embodiment, a conductive layer composed of, for example, silver may alternatively be formed.

The exposed sections of the electrode pattern 14 include the electrode terminals 14a electrically connected (conducted) to the light-emitting elements 20, sections corresponding to the anode electrode (anode land or anode connector) 21 and the cathode electrode (cathode land or cathode connector) 22 that are connected to external wires or an external device, and sections corresponding to the anode mark 23 and the cathode mark 24. The anode mark 23 and the cathode mark 24 may be formed on the insulation layer 30.

Furthermore, with regard to a connection method between the light-emitting device 4 and the external wires or the external device, the anode electrode 21 and the cathode electrode 22 may be connected to the external wires or the external device by soldering, or the anode electrode (anode land or anode connector) 21 and the cathode electrode (cathode land or cathode connector) 22 may be connected to the external wires or the external device via connectors respectively connected thereto.

[Insulation Layer 30 Having Light Reflectivity]

As shown in FIG. 1, in the substrate 10, the insulation layer 30 having light reflectivity is formed on the intermediate layer 13 and sections of the electrode pattern 14 such that the sections of the electrode pattern 14 are exposed.

The insulation layer 30 includes the glass sheet 31, which is a mesh structural member, and the reflection layer 32 composed of a white insulation material that reflects the light from the light-emitting elements 20. The glass sheet 31 is covered by the reflection layer 32. Accordingly, the insulation layer 30 has the mesh glass sheet 31, thereby achieving an effect of preventing the reflection layer 32 formed on the intermediate layer 13 and the sections of the electrode pattern 14 from delaminating from the intermediate layer 13 and the electrode pattern 14, which are under layers.

In the first embodiment, the reflection layer 32 is formed of an insulation layer containing a ceramic material, and the layer thickness thereof can be set between, for example, about 10 μm and 500 μm in view of the reflectivity of the substrate 10. The upper limit for the thickness of the reflection layer 32 is limited by the thickness of the electrode pattern 14. Since the copper electrode pattern 14 absorbs light when exposed, the reflection layer 32 needs to have enough thickness for entirely covering the electrode pattern 14 excluding the sections that have to be exposed. For example, if the electrode pattern 14 is given a thickness of 300 μm for the purpose of enhancing the heat dissipation in the substrate 10, the insulation layer 30 should also be given an optimal thickness of 300 μm or smaller for covering this. If the electrode pattern 14 is given a thickness of 500 μm, the reflection layer 32 should also be given an optimal thickness of 500 μm or smaller.

Because the thermal conductivity of the insulation layer 30 is lower than that of the intermediate layer 13 described above, it is preferable that the layer thickness of the reflection layer 32 be as small as possible for obtaining desired reflectivity. As the thickness for achieving this purpose, it is appropriate to set the layer thickness of the reflection layer 32 to between about 50 μm and 100 μm. If the maximum thickness of the electrode pattern 14 is large and it is not possible to sufficiently cover with this thickness, a third insulation layer may be interposed between the intermediate layer 13 and the reflection layer 32, and the thermal conductivity of this layer is desirably higher than that of the reflection layer 32. The third insulation layer may be an insulation layer in which a glass-based binder or a resinous binder contains ceramic particles with good heat dissipation, may be a ceramic layer formed by, for example, the spraying or AD method, or may be an alumina layer identical to the intermediate layer 13.

In the first embodiment, the reflection layer 32 having light reflectivity is formed of an insulation layer containing alumina and titanium oxide particles, which are ceramic particles having light reflectivity, and this insulation layer is formed by drying and thermally curing the resin using a resinous binder.

The thickness of the mesh-woven glass sheet 31, which is a structural member to be incorporated in the insulation layer 30, is substantially twice that of glass yarns to be used. Specifically, if the thickness of each glass yarn is 50 μm, the thickness of the glass sheet (glass cloth) would be twice the thickness thereof, which is 100 μm. A glass yarn with a 50-μm thickness may be formed of a single strand of glass fiber with a 50-μm thickness or may be a glass yarn with a diameter of 50 μm formed by intertwining a plurality of thinner strands of glass fiber. For example, by intertwining 20 or so strands of 10-μm-thick glass fiber to obtain a 50-μm-thick glass yarn, a glass yarn that is strong against tension can be formed. It is preferable to use the glass sheet 31 made by using yarns formed by intertwining strands of glass fiber since it has strong tolerance against expansion and contraction stress of resin.

By giving the mesh loops of the glass sheet 31 larger dimensions than the planar dimensions of the light-emitting elements 20, the number of glass yarns extending upon the electrode terminals 14a of the electrode pattern 14 can be reduced when placing the glass sheet over the intermediate layer 13 and the electrode pattern 14. A yarn still extending upon the electrode terminals 14a after the insulation layer 30 is formed has to be removed by, for example, grinding.

Furthermore, openings may be preliminarily formed in the mesh-woven glass sheet 31, such that the yarns of the glass sheet are exposed without overlapping the electrode terminals 14a of the electrode pattern 14.

The material of the mesh structural member constituting the insulation layer 30 is preferably composed of glass, similar to the glass sheet 31. This is because glass has excellent light and heat resisting properties. The material of the mesh structural member constituting the insulation layer 30 may be a material with a smaller coefficient of linear expansion than that of the reflection layer 32 or a material with a smaller coefficient of linear expansion than that of the sealing resin 16 to be used when used as a light-emitting device. As an alternative to glass, aromatic polyamide fiber (aramid fiber) or polyether ether ketone (PEEK) resin having high heat resisting properties and high strength may be used. Typical aramid fiber includes poly-p-phenyleneterephthalamide known as para-aramid fiber and poly-m-phenyleneisophthalamide known as meta-aramid fiber. Furthermore, a mesh structural member composed of epoxy-based resin, polyimide-based resin, or fluorine-based resin may be used as the structural member of the insulation layer 30. As an alternative to glass or resin, mesh-woven carbon fiber may be used.

Resin is suitable for the mesh structural member constituting the insulation layer 30 since resin normally has a coefficient of linear expansion larger than that of glass but smaller than that of silicone resin widely used as the sealing resin 16. Since para-aramid fiber and carbon fiber have an extremely small negative coefficient of linear expansion in the fiber axis direction and have excellent heat resisting properties and high strength, they are especially effectively used as the structural member for the insulation layer 30, in addition to glass.

In any case, in the insulation layer 30, the structural member formed of the mesh-woven glass sheet 31 is covered by the reflection layer 32, which is a white reflector. Accordingly, the structural member formed of the mesh-woven glass sheet 31 is used, thereby achieving the effect of preventing the reflection layer 32 having light reflectivity and formed on the intermediate layer 13 and on sections of the electrode pattern 14 from delaminating from the under layer.

Furthermore, the mesh-woven glass sheet 31 included in the insulation layer 30 has a coefficient of linear expansion smaller than that of the sealing resin 16 laminated on the insulation layer 30. Therefore, the insulation layer 30 pulled by the sealing resin 16 can be prevented from delaminating from the under layer. Accordingly, a light-emitting device 4 with excellent long-term reliability can be obtained.

The reflection layer 32 having light reflectivity may be formed by using spray coating. This method involves applying a raw material by spray coating, drying and curing the raw material as described above, and grinding a section of the reflection layer 32 such that the electrode terminals 14a, which are sections of the electrode pattern 14, are exposed. Alternatively, the reflection layer 32 may be formed by dripping an adequate amount of raw material using a dispenser device, preliminarily curing the raw material while applying pressure and temperature thereto using a pressing device, and then curing the raw material while holding it at a higher temperature in an oven.

Prior to forming the reflection layer 32 having light reflectivity, an undercoating process may be performed for forming an adequate undercoating (primer) or for forming an under layer by using an adhesive. By performing the undercoating process, the glass sheet 31 is preliminarily held to the under layer so that the structural member formed of the mesh-woven glass sheet 31 can be prevented from being blown off, delaminated, or uplifted from the under layer during spray coating or before the reflection layer 32 having light reflectivity is cured.

The undercoating (primer) and the raw material of the reflection layer 32 may be appropriately mixed so as to be used as a substitute for the adhesive. Specifically, after applying this mixture onto the under layer, the structural member formed of the mesh-woven glass sheet 31 may be placed on the under layer. Then, spray coating is performed in a state where the mixture is preliminarily cured and the glass sheet 31 is preliminarily held thereon, thereby ultimately forming the reflection layer 32 having light reflectivity.

The ceramic particles having light reflectivity used in the first embodiment are mixed particles of titanium oxide particles and alumina particles, but are not limited thereto. Alternatively, zirconia particles, silica (SiO₂) particles, or aluminum nitride particles may be used.

The term “ceramic” used here is not limited to metal oxide and may be in the broad sense of ceramic including aluminum nitride, and includes general inorganic solid materials. A freely-chosen material may be selected from these inorganic solid materials so long as the material is stable and has excellent heat resisting properties, excellent light reflectivity, and excellent light scattering properties. The only inadequate ceramic particles are the ones in which light absorption occurs. Specifically, for example, silicon nitride and silicon carbide are normally black and are not adequate as ceramic particles to be used in the reflection layer 32.

The reflection layer 32 having light reflectivity is formed by using a resinous binder containing ceramic particles having light reflectivity in the first embodiment, but may alternatively be formed by sintering a glass-based binder. As a method of sintering a glass-based binder, the glass-based binder is sintered using a sol-gel method in which the firing temperature is between 400° C. and 500° C., so that the reflection layer 32 can be formed.

Since an aluminum base is used as the base 12 composed of a metallic material, the insulation layer 30 is formed by sintering a glass-based binder using the sol-gel method in which the firing temperature is between 400° C. and 500° C. Alternatively, the insulation layer 30 may be formed by using a method other than the sol-gel method.

For example, there is an alternative method of forming a glass layer by re-melting low-melting-point glass particles that have been solidified with an organic binder. For the re-melting, a temperature of at least 800° C. to 900° C. is necessary. In the first embodiment in which a ceramic layer typified by alumina is used as the intermediate layer 13, if the base 12 composed of a metallic material has a high melting point, as described below, a method of forming the insulation layer 30 that requires such a high-temperature process can also be used.

Specifically, in such a high-temperature process, the melting point of 660° C. of the aluminum base is exceeded. Therefore, in such a case, a high-melting-point alloy material has to be used as the material of the base 12 by appropriately mixing the aluminum with impurities. If copper is used as the material of the base 12, copper can be used as-is since its melting point is 1085° C., but may be used by increasing the melting point of the base 12 by appropriately mixing impurities.

Due to having excellent light and heat resisting properties, a glass layer may be used for forming the reflection layer 32. However, in the first embodiment, silicone resin is used as resin having excellent heat and light resisting properties. As an alternative to silicone resin, for example, epoxy resin, fluorine resin, or polyimide resin may be used as a binder for the ceramic particles so as to form the reflection layer 32. Although silicone resin is inferior to glass in terms of heat and light resisting properties, silicone resin has a lower curing temperature than that in glass synthesis in the sol-gel method and thus enables an easier forming process. Therefore, silicone resin is often used in high-intensity illumination devices.

The insulation layer 30 according to this embodiment may further include a plurality of layers therein, as appropriate. With the insulation layer 30 having this configuration, a layer with high thermal conductivity can be disposed as a layer close to the intermediate layer 13 and a layer with high light reflectivity can be disposed as the opposite layer, so that a light-emitting-device substrate 10 having long-term reliability including high reflectivity, high heat dissipation, high dielectric strength, and high heat and light resisting properties can be realized. However, the expressions “high and low thermal conductivity and light reflectivity” used here are relative comparisons within the insulation layer 30.

[Light-Emitting Elements 20]

As shown in FIGS. 1 and 2, in the light-emitting device 4, the light-emitting elements 20 are packaged therein by being mounted on the substrate 10 and being sealed by the sealing resin 16. The light-emitting elements 20 are electrically connected to the terminals of the electrode pattern 14 by flip-chip bonding. The electrical connection may be established by using a commonly-used method, such as soldering, using bumps, or using a metallic paste.

Although LED elements are used as the light-emitting elements 20 in the first embodiment, EL elements may be used as an alternative. Furthermore, in the first embodiment, the light-emitting elements 20 are formed of sapphire substrates.

(Manufacturing Process of Substrate 10)

A manufacturing process of the light-emitting-device substrate 10 will be described below with reference to FIGS. 5 to 10. FIG. 5 illustrates the manufacturing method of the substrate 10 according to the first embodiment, and includes a cross-sectional view (a) of the base 12 having the intermediate layer 13 disposed thereon and a plan view (b) of the base 12 having the intermediate layer 13 disposed thereon.

First, as shown in FIG. 5, the intermediate layer 13 composed of alumina is formed by ejecting alumina particles at high speed by plasma spraying onto one side (i.e., a side at which the intermediate layer 13 is to be formed) of a 3-mm-thick aluminum base used as the base 12. The ceramic layer (intermediate layer 13) may be formed after performing a pretreatment for increasing the adhesiveness by roughening the surface of the base 12 by sandblasting.

Then, as shown in FIG. 5, the intermediate layer 13 having a thickness of 300 μm is completed (i.e., lamination of the intermediate layer 13 is completed).

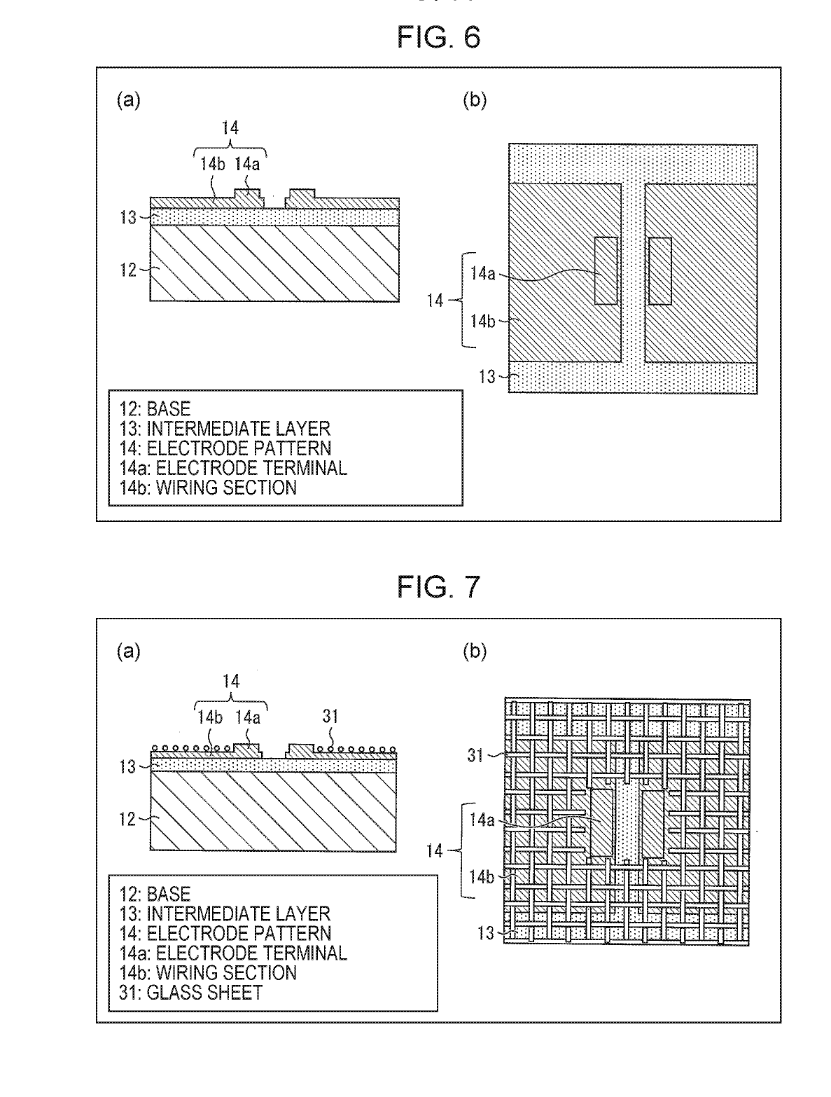

FIG. 6 illustrates the manufacturing method of the substrate 10 according to the first embodiment and includes a cross-sectional view (a) of the base 12 having the electrode pattern 14 disposed thereon and a plan view (b) of the base 12 having the electrode pattern 14 disposed thereon.

The base 12 having the intermediate layer 13 disposed thereon is subsequently conveyed to undergo a metallic-conductive-layer forming step. In the metallic-conductive-layer forming step, a copper conductive layer as a metallic conductive layer that is to become the electrode pattern 14 is formed with a thickness of 200 μm on the intermediate layer 13 on the base 12 having the intermediate layer 13 disposed thereon. Although the metallic conductive layer is formed by plasma spraying in the first embodiment, the metallic conductive layer may alternatively be formed by a method other than plasma spraying.

For example, after forming a thin metallic conductive layer by plasma spraying on the intermediate layer 13 formed by plasma spraying, a thick metallic conductive layer composed of copper may be deposited thereon by plating. Alternatively, for example, the metallic conductive layer may be formed by printing a metallic paste or by plating, as in the related art.

Subsequently, the base 12 having the metallic conductive layer disposed thereon in the metallic-conductive-layer forming step is conveyed to undergo an electrode-pattern forming step. Then, in the electrode-pattern forming step, the metallic conductive layer composed of copper formed on the intermediate layer 13 is etched in accordance with a known etching technique, thereby forming the electrode pattern 14 (i.e., the electrode terminals 14a and the wiring section 14b), as shown in FIG. 6.

The electrode terminals 14a are electrode posts for mounting light-emitting elements, and the wiring section 14b is wiring for electrically connecting adjoining electrode terminals to each other.

The anode electrode (anode land or anode connector) 21, the cathode electrode (cathode land or cathode connector) 22, the anode mark 23, and the cathode mark 24 may be formed in a manner similar to how the electrode terminals 14a for mounting light-emitting elements are formed, as described above.

FIG. 7 illustrates the manufacturing method of the substrate 10 according to the first embodiment, and includes a cross-sectional view (a) of the base 12 having the glass sheet 31 disposed thereon and a plan view (b) of the base 12 having the glass sheet 31 disposed thereon.

The base 12 having the electrode pattern 14 formed thereon in the electrode-pattern forming step is subsequently conveyed to undergo a reflection-layer forming step. In the reflection-layer forming step, a mesh-woven glass sheet is first disposed on the electrode pattern 14 and the exposed intermediate layer 13 so as to cover the intermediate layer 13 and the electrode pattern 14. In this case, as shown in FIG. 7, the electrode terminals 14a, of the electrode pattern 14, for mounting light-emitting elements are aligned with the openings in the mesh-woven glass sheet 31. Thus, the glass sheet 31 is not disposed on the surfaces of the electrode terminals 14a.

As shown in FIG. 7, the openings in the mesh-woven glass sheet 31 may be formed in advance by making holes in the glass sheet 31. Alternatively, the glass sheet 31 may have mesh loops with dimensions larger than the dimensions of the electrode terminals 14a and may be used in a manner such that the electrode terminals 14a are disposed within the mesh loops.

More specifically, for example, with respect to each light-emitting element 20 having a planar size of 1.0 mm at the four sides, an optimal glass sheet 31 may be selected and used within a range in which the glass sheet 31 has glass yarns with a diameter between 30 μm and 100 μm and mesh loops each having dimensions between, for example, 1.5 mm and 4.0 mm inclusive. By selecting a glass sheet 31 in which the mesh loops each have dimensions larger than the planar size of each light-emitting element 20, overlapping of the warp or weft yarns of the glass sheet 31 with the electrode pattern 14 can be avoided.

In contrast, if the glass sheet 31 used has small mesh dimensions of, for example, 0.5 mm or smaller with respect to each light-emitting element 20 having a planar size of 1.0 mm at the four sides, it is necessary to make holes in the glass sheet 31 so that the openings correspond to the positions where the light-emitting elements 20 are disposed.

In either case, the electrode terminals 14a of the electrode pattern 14 have to be exposed such that the yarns of the glass sheet 31 do not overlap with the electrode terminals 14a of the electrode pattern 14. Accordingly, the glass sheet 31 is disposed on the electrode pattern 14 and the intermediate layer 13.

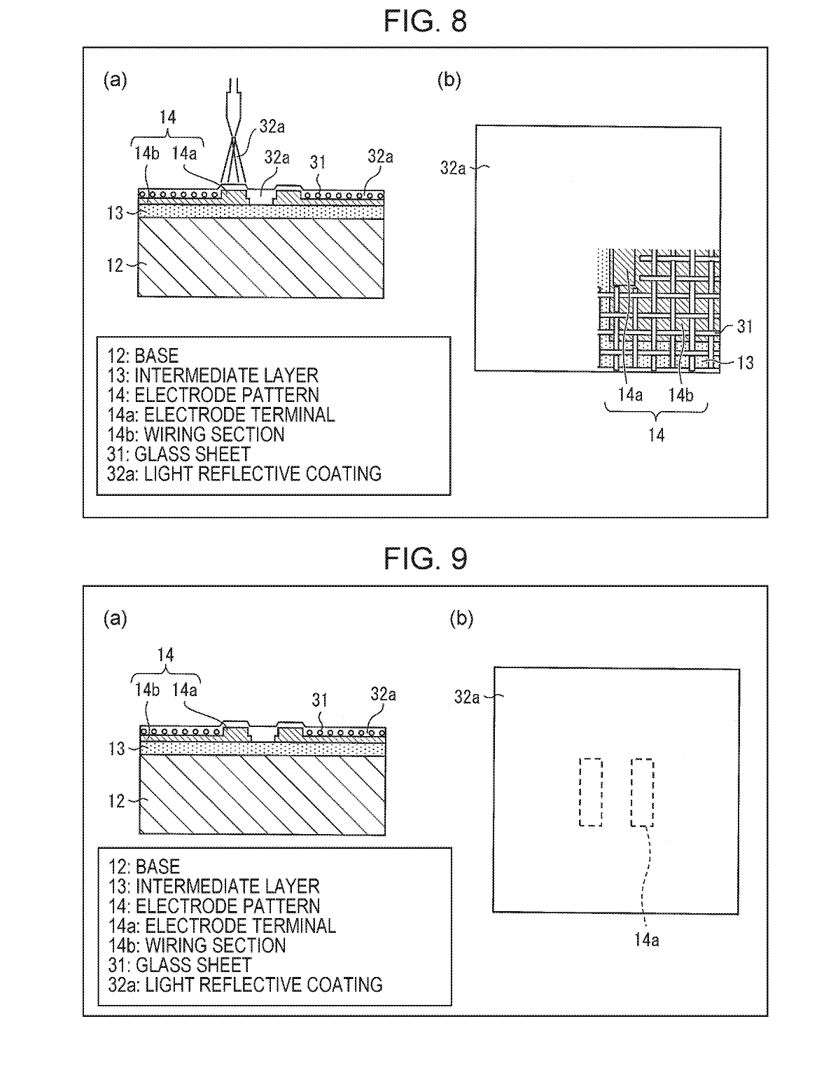

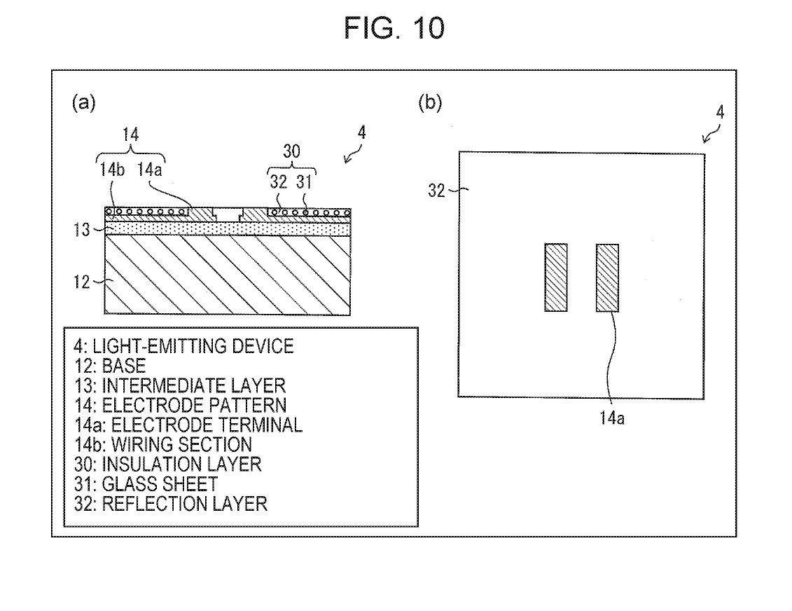

FIG. 8 illustrates the manufacturing method of the substrate 10 according to the first embodiment, and includes a cross-sectional view (a) of the base 12 to which a light reflective coating is applied and a plan view (b) of the base 12 to which the light reflective coating is applied. FIG. 9 illustrates the manufacturing method of the substrate 10 according to the first embodiment, and includes a cross-sectional view (a) of the base 12 in which the applied light reflective coating has cured and a cross-sectional view (b) of the base 12 in which the applied light reflective coating has cured. FIG. 10 illustrates the manufacturing method of the substrate 10 according to the first embodiment, and includes a cross-sectional view (a) of the base 12 having the reflection layer 32 formed thereon and a plan view of the base 12 having the reflection layer 32 formed thereon.

In the same reflection-layer forming step, the base 12 having the glass sheet 31 disposed thereon in the reflection-layer forming step is spray-coated with a light reflective coating 32a so as to cover the intermediate layer 13, the electrode pattern 14, and the mesh-woven glass sheet 31, as shown in FIG. 8. The light reflective coating 32a is to subsequently become the reflection layer 32. As an alternative to spray-coating, the light reflective coating 32a may be applied by any other method, such as screen-printing, using a dispenser, or using a pressing device to press and fix the light reflective coating 32a. In a case where spray-coating or screen-printing is used, the light reflective coating 32a may be cured by being pressed by a pressing device so that uplifting of the glass sheet 31 can be prevented, thereby ensuring the adhesiveness between the insulation layer 30 and the under layer. As an alternative to using a pressing device in this manner, the glass sheet 31 may be placed after performing an undercoating process using an adequate undercoating (primer) or adhesive prior to the reflection-layer forming step, as already described, thereby preventing, for example, uplifting of the glass sheet 31 in the reflection-layer forming step.

If the binder used in the light reflective coating 32a used here is resin, the resin is cured between 150° C. and 250° C. inclusive. Thus, the applied light reflective coating 32a can be cured.

Since the mesh glass sheet 31 is disposed within the light reflective coating 32a, the difference in linear expansion between the light reflective coating 32 a and the under layers, that is, the electrode pattern 14 and the intermediate layer 13, is alleviated even if heat is applied for curing the light reflective coating 32a, so that the light reflective coating 32a is unlikely to delaminate from the electrode pattern 14 and the intermediate layer 13. Therefore, reduction of the yield rate in the reflection-layer forming step can be prevented.

Subsequently, the cured light reflective coating that covers the electrode terminals 14a is removed, as shown in FIG. 10. Thus, the electrode terminals 14a are exposed, and the reflection layer 32 is formed. Specifically, the insulation layer 30 formed of the glass sheet 31 and the reflection layer 32 is formed.

In the case of this embodiment in which the insulation layer 30 having the reflection layer 32 with light reflectivity is formed by using spray-coating, since the electrode terminals 14a are covered by sections of the cured light reflective coating 32a, a step for exposing the electrode terminals 14a by removing these sections by grinding is necessary. Accordingly, the substrate 10 is completed.

Finally, with respect to the completed substrate 10, flip-chip-type LED chips serving as the light-emitting elements 20 are electrically connected to the electrode terminals 14a of the electrode pattern 14 in the substrate 10 by flip-chip bonding. Consequently, the substrate 10 having the light-emitting elements 20 mounted thereon shown in FIG. 1 can be completed. The light-emitting elements 20 and the electrode pattern 14 may be electrically joined by an appropriate method, such as an Au bump method or soldering.

Depending on the type of solder used, the electrode terminals 14a of the electrode pattern 14 may be plated with gold, where necessary. For example, if AuSn solder is used, Au plating is necessary. Multilayer plating, such as Ni/Pd/Au, is also permissible.

### Modification of First Embodiment

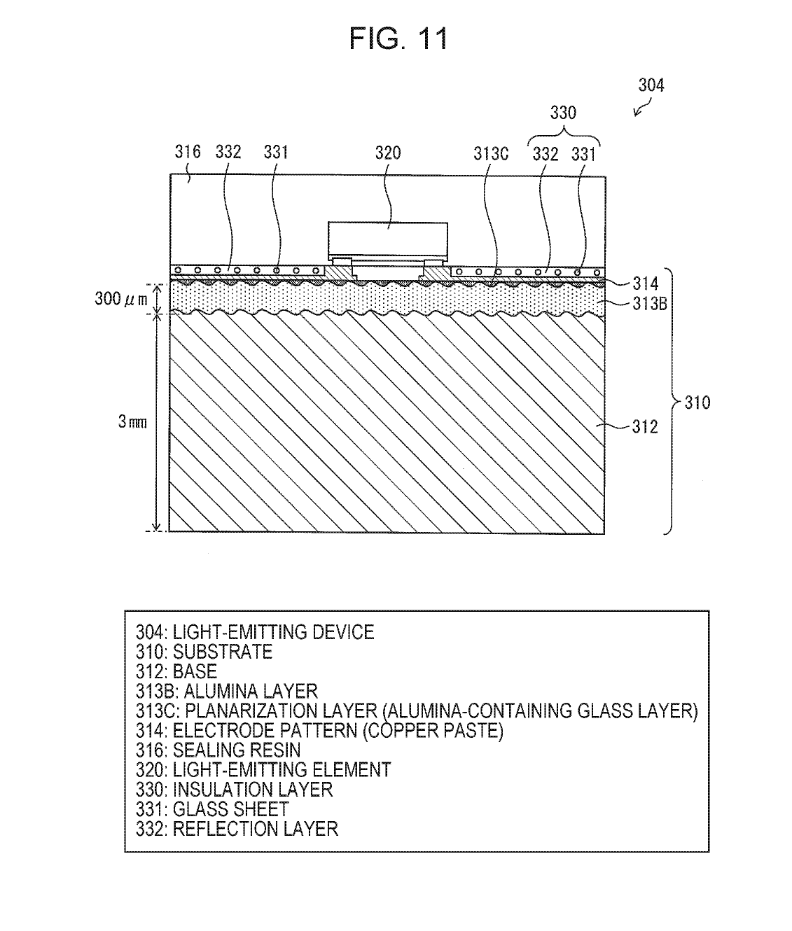

Next, a modification of the light-emitting device 4 according to this embodiment will be described with reference to FIG. 11. FIG. 11 is a cross-sectional view illustrating the configuration of a light-emitting device 304, which is a modification of the light-emitting device 4 according to this embodiment. The light-emitting device 304 includes light-emitting elements 320, sealing resin 316 that seals the light-emitting elements 320, and a substrate 310. The substrate 310 for the light-emitting device 304 includes a base 312, a sprayed alumina layer 313B, a planarization layer 313C, an electrode pattern 314, and an insulation layer (first insulation layer) 330. The insulation layer 330 includes a glass sheet 331, which is a mesh-woven structural member, and a reflection layer 332 containing the glass sheet 331 and composed of a white insulation material that reflects light from the light-emitting elements 320.

The substrate 310 differs from the substrate 10 of the light-emitting device 4 (see FIG. 1) in that the intermediate layer 13 is replaced with the sprayed alumina layer (second insulation layer) 313B and the planarization layer (second insulation layer) 313C, which is an alumina-containing glass layer that covers the sprayed alumina layer 313B. Furthermore, the substrate 310 is different in that the base 12 of the light-emitting device 4 is replaced with the base 312 having an irregular surface. Other configurations of the substrate 310 are similar to those of the substrate 10. Similar to the light-emitting elements 20, the light-emitting elements 320 are flip-chip-type LED chips. The glass sheet 331 and the reflection layer 332 have the same configurations and are composed of the same materials as the glass sheet 31 and the reflection layer 32, respectively.

In order to accurately form the electrode pattern 314 on the sprayed alumina layer 313B functioning as an intermediate layer, it is desirable that the surface of the intermediate layer be flat. However, the alumina layer 313B formed by spraying tends to have a surface with protrusions and recesses, and these protrusions and recesses normally have a depth between 20 μm and 40 μm inclusive, or even larger. Although the alumina layer 313B may have its surface planarized by grinding so as to function as an intermediate layer, it is easier to cover the alumina layer 313B with the planarization layer 313C formed of an alumina-containing glass layer and planarize the surface of the alumina layer 313B by filling in the protrusions and recesses.

The electrode pattern 314 including electrode terminals onto which the light-emitting elements 320 are to be mounted can be formed in a manner similar to the electrode pattern 14 of the light-emitting device 4. Accordingly, a foundation layer on which the electrode pattern 314, which is a copper metallic conductive layer, is to be formed is planarized so that the electrode pattern 314 can be formed stably and accurately by etching.

(Using Resin as Binder in Reflection Layer 32)

As shown in FIG. 1, in the light-emitting device 4, the insulation layer 30 disposed on the electrode pattern 14 and on the intermediate layer 13 is constituted of the structural member, which is formed of the mesh-woven glass sheet 31, and the reflection layer 32, which is a white reflector that covers the structural member.

By disposing the structural member formed of the mesh-woven glass sheet 31 within the reflection layer 32, the effect of preventing the reflection layer 32 from delaminating from the electrode pattern 14 and the intermediate layer 13, which are under layers, is most noticeable in a case where resin is used as the binder in the reflection layer 32, and especially in a case where the binder is silicone resin. This case will be described as a representative example.

Resin has a coefficient of linear expansion that is about five to ten times or sometimes even ten or more times that of alumina. In a case where alumina is used as the material of the intermediate layer 13 composed of a ceramic material, copper is used as the electrode pattern 14, and silicone resin is used as the binder of the reflection layer 32, delamination tends to occur at the boundary between the intermediate layer 13 and the reflection layer 32 and the boundary between the electrode pattern 14 and the reflection layer 32 due to a large difference between the coefficient of linear expansion of the intermediate layer 13 and the electrode pattern 14 and the coefficient of linear expansion of the reflection layer 32. When the mesh-woven glass sheet 31 having glass, which has a coefficient of linear expansion smaller than that of resin, as the raw material is used as the structural member in the reflection layer 32, the expansion and contraction of the resin are localized at small divisions (mesh loops) forming the mesh structure of the glass sheet, and the thermal expansion and contraction of the glass sheet 31 are smaller than those of resin, whereby the thermal expansion and contraction of the reflection layer 32 can be suppressed. As a result, stress occurring with thermal expansion and contraction acting on the boundary between the reflection layer 32 and the intermediate layer 13 or between the reflection layer 32 and the electrode pattern 14 is reduced, thereby exhibiting the effect of preventing the reflection layer 32 from delaminating from the intermediate layer 13 or the electrode pattern 14, which is an under layer.

A similar effect is more noticeably achieved in the case of the light-emitting device 4 in which the reflection layer 32 is covered by the sealing resin 16, as in FIG. 2. In a case where the coefficient of linear expansion of the sealing resin 16 is equal to or larger than that of the reflection layer 32, the reflection layer 32 receives the effect of the expansion and contraction of the sealing resin 16 and thus tends to receive stress. However, when the mesh-woven glass sheet 31 with glass, which has a coefficient of linear expansion smaller than that of resin used in the sealing resin 16, as the raw material is used as the structural member within the reflection layer 32, stress occurring with thermal expansion and contraction acting on the boundary between the reflection layer 32 and the intermediate layer 13 or between the reflection layer 32 and the electrode pattern 14 is reduced in accordance with the above-described reason, thereby exhibiting the effect of preventing the reflection layer 32 pulled by the sealing resin 16 from delaminating from the intermediate layer 13 or the electrode pattern 14, which is an under layer, or exhibiting the effect of preventing the electrode pattern 14 from delaminating from the intermediate layer 13.

As described above in the specific example, the mechanism by which delamination can be reduced by using the mesh-woven glass sheet 31 as the structural member within the reflection layer 32 is summarized into two following points: (1) the thermal expansion and contraction of the reflection layer 32 can be localized at small divisions (mesh loops) forming the mesh structure of the glass sheet 31 and (2) the coefficient of linear expansion of the reflection layer 32 is pulled toward the coefficient of linear expansion of the glass sheet 31 so as to become closer to the coefficient of linear expansion of the intermediate layer 13 or the electrode pattern 14. Consequently, thermal stress acting on the boundary between the reflection layer 32 and the intermediate layer 13 and on the boundary between the reflection layer 32 and the electrode pattern 14 is reduced.

By using the structural member formed of the mesh-woven glass sheet 31 within the reflection layer 32 as the insulation layer 30, the substrate 10 according to this embodiment has overcome the problem of delamination of the reflection layer having high light reflectivity and has successfully achieved long-term reliability for the first time, thereby realizing an ideal substrate 10 for a light-emitting device 4 that simultaneously satisfies three conditions, namely, high light reflectivity, low thermal resistance (high heat dissipation), and high dielectric strength, which are required as the substrate 10 for the light-emitting device 4 that performs high-intensity illumination.

It is clear from the above description that, in the substrate 10 according to this embodiment, the intermediate layer 13 formed of a ceramic layer and the electrode pattern 14 composed of copper are provided between the base 12 composed of aluminum and the reflection layer 32. In this case, the mesh-woven glass sheet 31 is used as the structural member within the reflection layer 32. As a result, a substrate 10 for a light-emitting device 4 suitable for high-intensity illumination and having long-term reliability, particularly, long-term reliability of the reflection layer 32, in addition to high reflectivity, high heat dissipation, and high dielectric strength is achieved. With the substrate 10 according to this embodiment, such a light-emitting-device substrate can be provided in a highly mass productive manner. The light-emitting device 4 or the illuminating apparatus 1 using this substrate 10 is highly mass productive and can realize long-term-reliable high-intensity illumination.

Furthermore, the mesh-woven glass sheet 31 included in the insulation layer 30 has a coefficient of linear expansion smaller than that of the sealing resin 16 laminated on the insulation layer 30. Therefore, the insulation layer 30 pulled toward the sealing resin 16 can be prevented from delaminating from an under layer. Accordingly, a light-emitting device 4 and an illuminating apparatus 1 with long-term reliability can be obtained.

Accordingly, in the light-emitting-device substrate and the manufacturing method of the light-emitting-device substrate according to this embodiment, the insulation layer 30 (first insulation layer) having light reflectivity is formed on the intermediate layer 13 (second insulation layer) having high thermal conductivity and on the wiring section 14b, which is the remaining section of the electrode pattern 14, such that the electrode terminals 14a, which are sections of the electrode pattern 14, are exposed. Since the structural member formed of the mesh-woven glass sheet 31 is incorporated in the insulation layer 30, the insulation layer 30 can be prevented from delaminating, thereby realizing a light-emitting-device substrate having long-term reliability and high reflectivity and a manufacturing method of the light-emitting-device substrate.

With the substrate 10 and the manufacturing method of the substrate 10 according to this embodiment, a light-emitting-device substrate having long-term reliability including high reflectivity, high heat dissipation, dielectric strength, and heat and light resisting properties as well as a manufacturing method of the light-emitting-device substrate can be realized.

### Second Embodiment

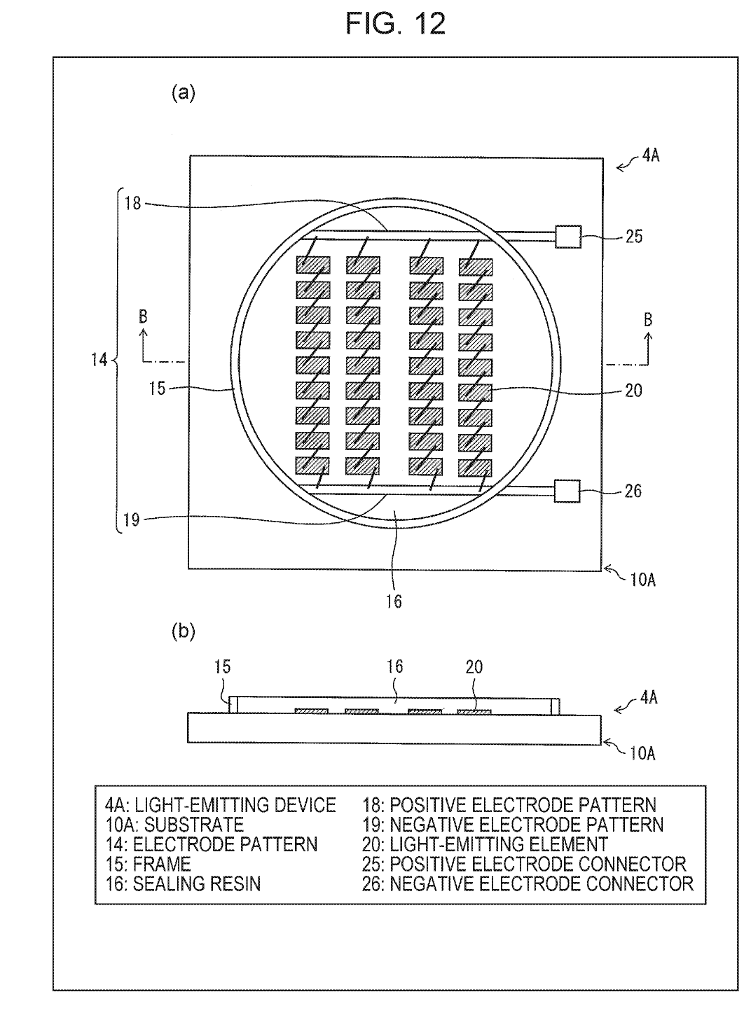

A second embodiment of the present invention will be described below with reference to FIGS. 12 to 17. For the sake of convenience, components having functions identical to those of the components described in the above embodiment are given the same reference signs, and descriptions thereof will be omitted.

(Configuration of Light-emitting device 4A)

The illuminating apparatus 1 (see FIG. 3) may include a light-emitting device 4A shown in FIG. 12 in place of the light-emitting device 4. FIG. 12 includes a plan view (a) illustrating the configuration of the light-emitting device 4A according to the second embodiment and a cross-sectional view (b) taken along a plane BB shown in (a).

The light-emitting device 4A is a COP (chip-on-board) type light-emitting device having a plurality of light-emitting elements 20, formed of LED elements or EL (electro-luminescence) elements, mounted on a substrate (light-emitting-device substrate) 10A. For simplification, the number of light-emitting elements 20 is significantly reduced in FIG. 12 for the sake of convenience. In other drawings, including FIG. 12, the dimensions, shapes, and numbers do not necessarily match those in the actual substrate, light-emitting elements, and light-emitting device.

A ring-shaped frame 15 provided on the periphery of the sealing resin 16 and surrounding the plurality of light-emitting elements 20 is provided on the substrate 10A. The sealing resin 16 fills the interior of the frame 15 so as to seal the light-emitting elements 20. The sealing resin 16 includes a fluorescent material that is excited by light output from the light-emitting elements 20 and that converts the output light into light having a different wavelength. With this configuration, the light-emitting device 4A surface-emits light from the surface of the sealing resin 16.

Since the light-emitting device 4A has many light-emitting elements 20 integrated therein, an electric power of 10 W, 50 W, 100 W, or 100 W or higher is input to the light-emitting device 4A, and high-intensity output light is obtained from the light-emitting device 4A receiving the electric power. For example, in order to realize a high-output light-emitting device 4A with an input power of about 100 W by integrating mid-size light-emitting elements 20 of about 500 μm by 800 μm on the substrate 10A, it is necessary to integrate a large number of light-emitting elements 20, namely, from about 300 to 400 light-emitting elements 20. Since the heat generated from the light-emitting device 4A increases when a large number of light-emitting elements 20 are integrated, the light-emitting device 4A may be attached to the heatsink 2, which has an extremely large volume as compared with the light-emitting device 4A (light-emitting device 4 in FIG. 4), as shown in FIG. 4, so as to ensure the heat dissipation from the light-emitting device 4A.

The light-emitting elements 20 used may be LED chips, such as blue LED chips, purple LED chips, and ultraviolet LED chips. Alternatively, EL elements may be used as the light-emitting elements 20.

The fluorescent material contained in the sealing resin 16 may be, for example, a fluorescent material that emits any one of blue, green, yellow, orange, and red colors, or a combination of a plurality of freely-chosen fluorescent materials. Thus, output light with a desired color can be output from the light-emitting device 4A. Alternatively, the fluorescent material of the sealing resin 16 may be omitted. Specifically, light-emitting elements 20 of three colors with different light emission wavelengths, namely, blue, green, and red colors, may be arranged on the substrate 10A, light-emitting elements 20 with a combination of two freely-chosen colors may be arranged, or monochromatic light-emitting elements 20 may be arranged.

(Configuration of Substrate 10A)

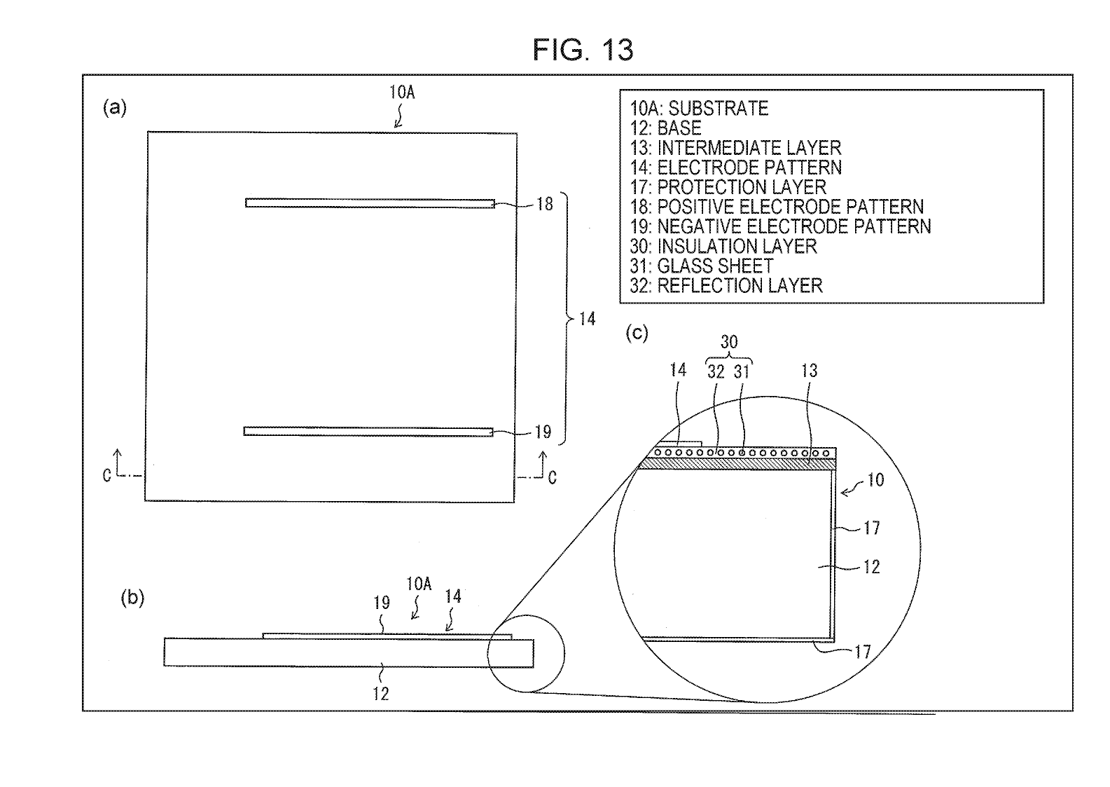

The configuration of the substrate 10A will be described below with reference to FIG. 13. FIG. 13 includes a plan view (a) illustrating the configuration of the substrate 10 provided in the light-emitting device 4A, a cross-sectional view (b) taken along a plane CC shown in (a), and a partially enlarged view (c) of the cross-sectional view.

The substrate 10A is used in the light-emitting device 4A (see FIG. 12) having a large number of light-emitting elements 20 (see FIG. 12) disposed thereon.

The substrate 10A includes a base 12 composed of a metallic material. An aluminum base can be used as the base 12. As shown in FIG. 13(c), an intermediate layer 13, an insulation layer 30, and an electrode pattern 14 are laminated in this order on the surface of the base 12. The insulation layer 30 is formed of a mesh glass sheet 31 and a reflection layer 32.

Similar to the light-emitting device 4 shown in FIG. 1, the intermediate layer 13 is formed to cover the surface of the base 12. The insulation layer 30 is formed on the upper surface of the intermediate layer 13 on the surface of the base 12. In other words, the intermediate layer 13 is formed between the insulation layer 30 and the base 12.

The electrode pattern 14 is formed on the insulation layer 30. As shown in FIG. 13(a), the electrode pattern 14 has a positive electrode pattern (wiring pattern) 18 and a negative electrode pattern (wiring pattern) 19. The electrode pattern 14 is constituted of an under-layer circuit pattern (not shown) formed of a metallic conductive layer and plating that covers the under-layer circuit pattern. The electrode pattern 14 is wiring for establishing an electrical connection with the light-emitting elements 20 (see FIG. 12) disposed on the substrate 10. As shown in FIG. 12(a), the light-emitting elements 20 are connected to the electrode pattern 14 by, for example, wires, and the insulation layer 30 has face-up-type light-emitting elements 20 mounted thereon.

As shown in FIG. 12(a), the light-emitting elements 20 are connected to the positive electrode pattern 18 and the negative electrode pattern 19. The positive electrode pattern 18 is connected to a positive electrode connector 25 for connecting the light-emitting elements 20 to external wiring or an external device via the positive electrode pattern 18. The negative electrode pattern 19 is connected to a negative electrode connector 26 for connecting the light-emitting elements 20 to the external wiring or the external device via the negative electrode pattern 19. As an alternative to the positive electrode connector 25 and the negative electrode connector 26, the positive electrode pattern 18 and the negative electrode pattern 19 may be constituted of lands and be directly connected to the external wiring or the external device by soldering.

In the case where the positive electrode pattern 18 and the negative electrode pattern 19 are to be connected to the external wiring or the external device by using the positive electrode connector 25 and the negative electrode connector 26, the positive electrode pattern 18 and the negative electrode pattern 19 may individually be provided with lands, and the positive electrode pattern 18 and the negative electrode pattern 19 may be connected to the positive electrode connector 25 and the negative electrode connector 26, respectively, via the lands.

In the light-emitting device 4A according to this embodiment, the insulation layer 30 having the intermediate layer 13, which is a thermally-conductive ceramic insulator, and the reflection layer 32, which is a light-reflective ceramic insulator, is formed as an insulation layer between the electrode pattern 14 and the base 12. Moreover, the intermediate layer 13 is formed between the insulation layer 30 and the base 12. When the intermediate layer 13 and the insulation layer 30 are compared with each other, it is desirable that the former be higher than the latter in terms of thermal conductivity, and that the latter be higher than the former in terms of light reflectivity. With the above configuration, the substrate 10A can stably ensure high thermal conductivity, high dielectric strength, and high reflectivity. Furthermore, it is desirable that the thickness of the insulation layer 30 be smaller than the thickness of the intermediate layer 13. The individual layers will be described in detail below.

[Specific Configuration of Base 12]

An example of the base 12 that can be used is an aluminum plate with a vertical side of 50 mm, a horizontal side of 50 mm, and a thickness of 3 mm. Advantages of using aluminum as the base 12 include lightness in weight, good machinability, and high thermal conductivity. The base 12 may contain a component other than aluminum to an extent that does not interfere with an anodic oxidation process for forming a protection layer 17.

The material of the base 12 is not limited to that described above. For example, a copper material may be used as the material of the base so long as it is a metallic material that is light in weight, has good machinability, and has high thermal conductivity. A copper alloy containing a component in addition to copper may also be used.

[Specific Configuration of Intermediate Layer 13]

The intermediate layer 13 is formed by laminating a ceramic layer on the base 12 by plasma spraying and has insulation properties. In other words, the intermediate layer 13 contains a ceramic material formed by plasma spraying. As will be described later, since the insulation layer 30 needs to have enough thickness for ensuring a light reflecting function, there is conceivably a case where the substrate 10A lacks required dielectric strength. The intermediate layer 13 reinforces the dielectric strength lacking with the insulation layer 30 alone.

The intermediate layer 13 in the light-emitting device 4A according to this embodiment has the same function, uses the same material, and is formed by the same method as the intermediate layer 13 in the light-emitting device 4 according to the first embodiment.

[Specific Configuration of Insulation Layer 30]

The insulation layer 30 includes the glass sheet 31, which is a mesh structural member, and the reflection layer 32 composed of a white insulation material that reflects the light from the light-emitting elements 20. The reflection layer 32 contains a ceramic material having light reflectivity and has insulation properties. Accordingly, the insulation layer 30 reflects the light from the light-emitting elements 20. The insulation layer 30 is disposed between the electrode pattern 14 and the intermediate layer 13, or in other words, between the electrode pattern 14 and the base 12.

The glass sheet 31 is covered by the reflection layer 32. Accordingly, the insulation layer 30 has the mesh glass sheet 31, thereby achieving an effect of preventing the reflection layer 32 formed on the intermediate layer 13 from delaminating from the intermediate layer 13, which is an under layer. Especially in a case where the insulation layer 30 is covered by the sealing resin 16 shown in FIG. 12, there is an increased possibility in that the reflection layer 32 formed on the intermediate layer 13 may delaminate from the intermediate layer 13, which is an under layer, by being pulled by the sealing resin 16, which thermally expands and contracts. However, since the insulation layer 30 has the mesh glass sheet 31, the effect of preventing the delamination is noticeably achieved.

In the second embodiment, the reflection layer 32 is formed of an insulation layer containing a ceramic material, and the layer thickness thereof can be set between, for example, about 10 μm and 100 μm in view of the reflectivity of the substrate 10A. Because the substrate 10A fabricated in the second embodiment is a substrate in which the light-emitting elements 20 are to be directly placed on the insulation layer 30, it is more preferable that the layer thickness be 50 μm or smaller for enhancing the heat dissipation. The reflection layer 32 is formed as an insulating reflection layer containing ceramic particles at the outermost layer of the substrate 10A by mixing ceramic particles with a glass-based binder or a resinous binder having light and heat resisting properties and curing the mixture by, for example, drying or firing. In the second embodiment, the reflection layer 32 is a mixed layer of a light-reflective ceramic material and silicone resin. The reflection layer 32 contains alumina and titanium oxide as light-reflective ceramic particles and is formed by causing resin to cure by using a resinous binder.

A glass-based binder is composed of a sol-like material that synthesizes glass particles by a sol-gel reaction. As an alternative to silicone resin, the resinous binder may be composed of epoxy resin, fluorine resin, or polyimide resin having excellent heat and light resisting properties as well as high transparency. A resinous binder normally has a lower curing temperature than a glass binder and can therefore be readily manufactured. On the other hand, a glass-based binder is characterized in having excellent heat and light resisting properties as well as high heat conductivity, as compared with a resinous binder.

The reflection layer 32 in the light-emitting device 4A according to this embodiment has the same function, uses the same material, and is formed by the same method as the reflection layer 32 having light reflectivity according to the first embodiment.

(Manufacturing Process of Substrate 10A)

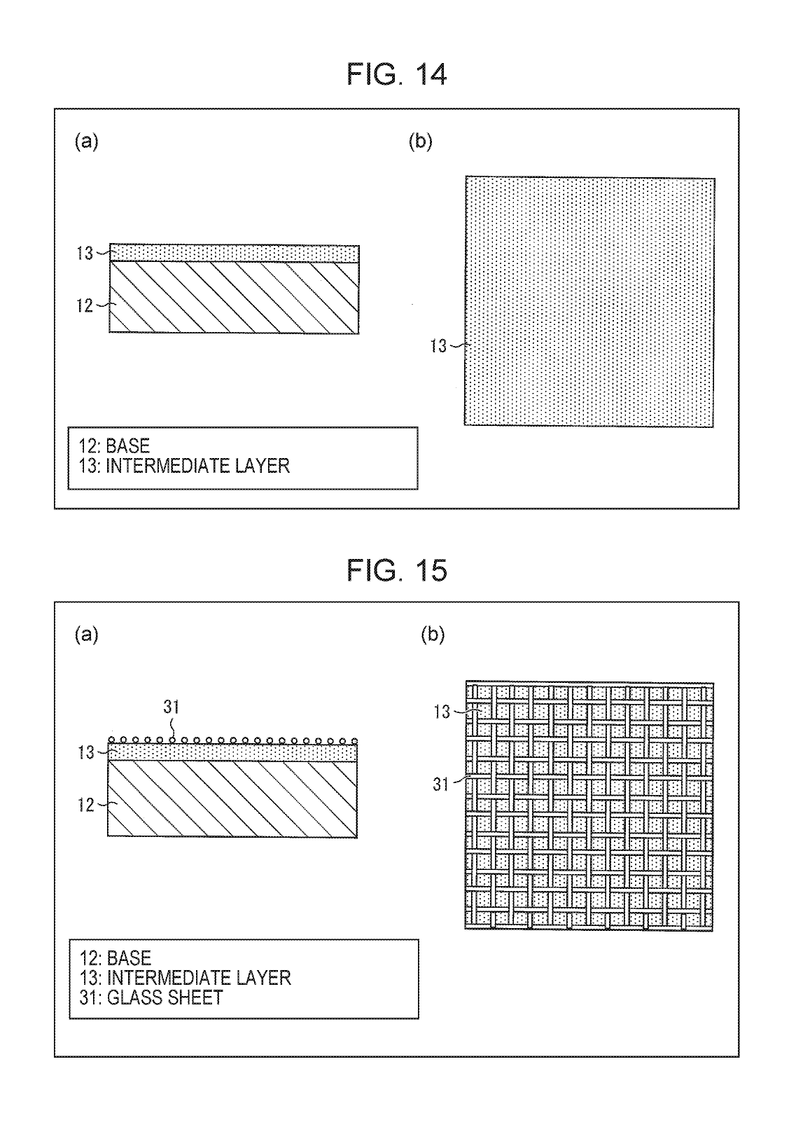

Next, the manufacturing method of the substrate 10A according to the second embodiment will be described with reference to FIGS. 14 to 17. FIG. 14 illustrates the manufacturing method of the substrate 10A according to the second embodiment, and includes a cross-sectional view (a) of the base 12 having the intermediate layer 13 disposed thereon and a plan view (b) of the base 12 having the intermediate layer 13 disposed thereon.

First, as shown in FIG. 14, the intermediate layer 13 is formed on the surface of the base 12 composed of aluminum (intermediate-layer forming step). The intermediate layer 13 is formed by laminating an aluminum layer on the base 12 by plasma spraying.

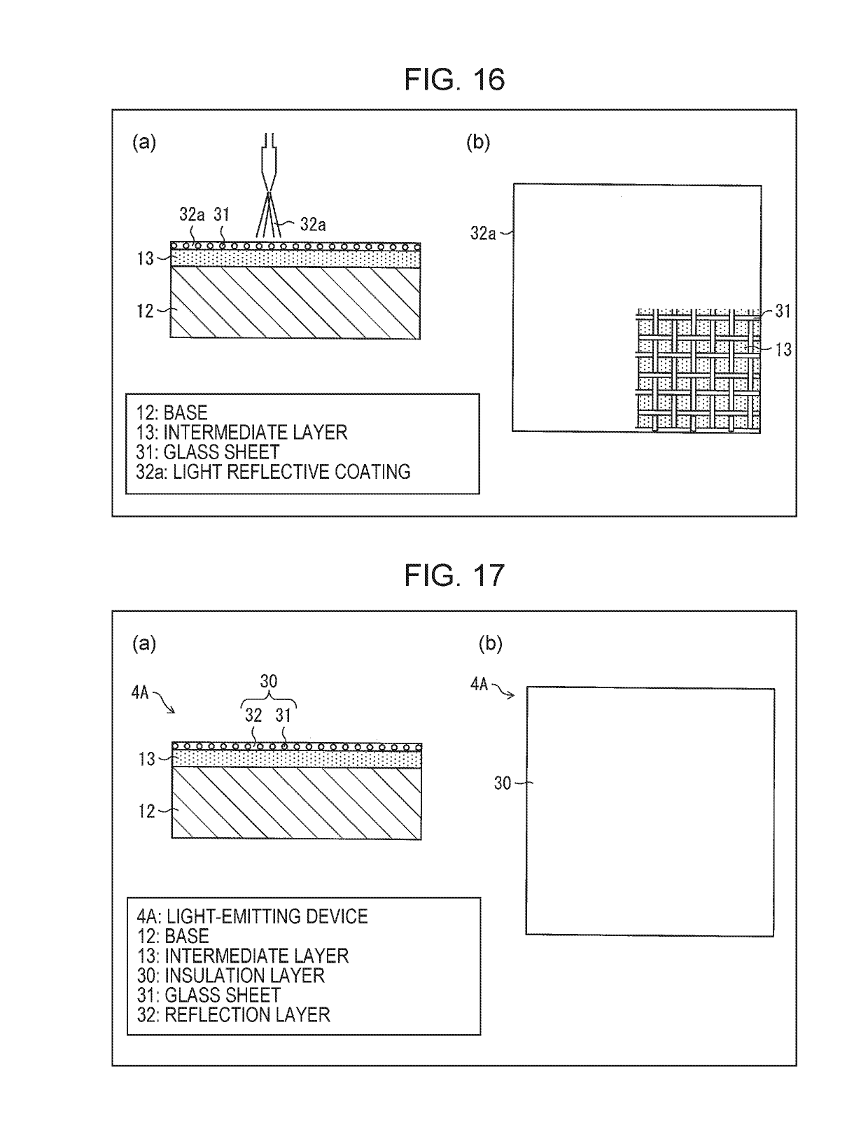

FIG. 15 illustrates the manufacturing method of the substrate 10A according to the second embodiment, and includes a cross-sectional view (a) of the base 12 having the glass sheet 31 disposed thereon and a plan view (b) of the base 12 having the glass sheet 31 disposed thereon. FIG. 16 illustrates the manufacturing method of the substrate 10A according to the second embodiment, and includes a cross-sectional view (a) of the base 12 to which a light reflective coating is applied and a plan view (b) of the base 12 to which the light reflective coating is applied. FIG. 17 illustrates the manufacturing method of the substrate 10A according to the second embodiment, and includes a cross-sectional view (a) of the base 12 having the reflection layer 32 formed thereon and a plan view (b) of the base 12 having the reflection layer 32 formed thereon.

The base 12 having the intermediate layer 13 formed thereon in the intermediate-layer forming step is subsequently conveyed to undergo a reflection-layer forming step. Then, as shown in FIG. 15, in the reflection-layer forming step, the mesh-woven glass sheet 31 is disposed on the upper surface of the intermediate layer 13 on the surface of the base 12. Then, as shown in FIG. 16, in the reflection-layer forming step, the light reflective coating 32a formed of ceramic particles mixed in a resinous binder having light and heat resisting properties is applied to cover the intermediate layer 13 and the mesh-woven glass sheet. As an alternative to spray-coating, the light reflective coating 32a may be applied by any other method, such as screen-printing, using a dispenser, or using a pressing device to press and fix the light reflective coating 32a. In a case where spray-coating or screen-printing is used, the light reflective coating 32a may be cured by being pressed by a pressing device so that uplifting of the glass sheet can be prevented, thereby ensuring the adhesiveness between the reflection layer 32 and the under layer. As an alternative to using a pressing device in this manner, the glass sheet 31 may be placed after performing an undercoating process using an adequate undercoating (primer) or adhesive prior to the reflection-layer forming step, as already described in the first embodiment, thereby preventing, for example, uplifting of the glass sheet 31 in the reflection-layer forming step. If the binder used in the coating used here is resin, the resin is cured between 150° C. and 250° C., whereby a light reflection layer can be formed, as shown in FIG. 17.

As a method of forming the reflection layer 32, the reflection layer 32 may be formed by using a glass-based binder in place of the resinous binder to synthesize a glass material by a sol-gel reaction. Furthermore, instead of using the sol-gel method, the reflection layer 32 may be formed by forming a glass layer by re-melting low-melting-point glass particles that have been cured with an organic binder. For re-melting the low-melting-point glass particles that have been cured with the organic binder, a temperature of at least 800° C. to 900° C. is necessary. In this embodiment, since a ceramic layer typified by alumina is used as the intermediate layer 13, a method of forming the reflection layer 32 that requires such a high-temperature process can also be used.

However, such a high temperature exceeds the melting point of 660° C. of aluminum used in the base 12. Therefore, a high-melting-point alloy material obtained by appropriately mixing the base 12 with impurities has to be used. Because the melting point of copper is 1085° C. and is thus higher than the melting point of aluminum, if copper is used in the base 12, the method of re-melting the low-melting-point glass can be used. Needless to say, the method of re-melting the low-melting-point glass may be used after appropriately mixing the base 12 with impurities to give the base a high melting point.

Due to having excellent light and heat resisting properties, glass is preferably used as the material for forming the reflection layer 32. Alternatively, resin having excellent light and heat resisting properties, such as silicone resin, epoxy resin, polyimide resin, or fluorine resin, may be used as the binder for the ceramic particles. Although the aforementioned resin is inferior to glass in terms of heat and light resisting properties, the curing temperature of the resin is lower than the curing temperature in glass synthesis according to the sol-gel reaction in the glass raw material. Thus, when resin is used as the binder for the ceramic particles, the reflection layer 32 can be readily formed.

In the reflection-layer forming step according to this embodiment, since the mesh glass sheet 31 is disposed within the light reflective coating 32a, the difference in thermal contraction rate between the light reflective coating 32a and the intermediate layer 13, which is an under layer thereof, is alleviated even if heat is applied for curing the light reflective coating 32a, so that the light reflective coating 32a is unlikely to delaminate from the intermediate layer 13. Therefore, reduction of the yield rate in the reflection-layer forming step can be prevented.

Then, in order to ultimately obtain the substrate 10A shown in FIG. 13 by using the base 12 having the reflection layer 32 formed thereon shown in FIG. 17, an anodized aluminum layer is first formed on the base 12, which has the reflection layer 32 formed thereon, by anodizing the exposed sections of the base 12, and a sealing process is further performed thereon so that the protection layer 17 (see FIG. 13(c)) is completed.

Subsequently, a circuit pattern as a foundation of the electrode pattern 14 is drawn by, for example, printing on the upper surface of the reflection layer 32 by using a metallic paste composed of resin containing metallic particles. The circuit pattern is dried so that a foundation circuit pattern, which is to subsequently become the electrode pattern 14, is formed (foundation-circuit-pattern forming step). Then, electrode metal is deposited on the foundation circuit pattern by performing a plating process, so that the electrode pattern 14 is formed, as shown in FIG. 13(c) (electrode-pattern forming step).

The base 12 is already covered by the high-reflectivity reflection layer 32 containing a ceramic material, the intermediate layer 13, and the protection layer 17, which is an anodized aluminum film. Therefore, with the plating solution used in the plating process in the electrode-pattern forming step, the electrode metal can be efficiently deposited only on the foundation circuit pattern from the plating solution without corroding the base 12.

The reasons why the substrate 10A according to this embodiment can prevent the insulation layer 30 from delaminating from the intermediate layer 13, which is an under layer, as compared with a substrate having a metallic base in the related art, will be described below.

As described above, the insulation layer 30 is formed of the glass sheet 31, which is a mesh structural member, and the reflection layer 32 covering the glass sheet 31. By disposing a structural member formed of a mesh-woven glass sheet within the reflection layer 32, the effect of preventing the reflection layer 32 from delaminating from the intermediate layer 13, which is an under layer, is most noticeable when resin is used as the binder in the reflection layer 32, and especially when the binder is silicone resin. This will be described as a representative example.

Resin has a coefficient of linear expansion that is about five to ten times or sometimes even ten or more times that of alumina. In a case where alumina is used as the material of the intermediate layer 13 composed of a ceramic material and silicone resin is used as the binder in the reflection layer 32, delamination tends to occur readily at the boundary between the two layers due to a large difference in coefficient of linear expansion therebetween. When the mesh-woven glass sheet 31 having glass, which has a coefficient of linear expansion smaller than that of resin, as the raw material is used as the structural member in the reflection layer 32, the expansion and contraction of the resin are localized at small divisions (mesh loops) forming the mesh structure of the glass sheet, and the thermal expansion and contraction of the glass sheet 31 are smaller than those of resin, whereby the thermal expansion and contraction of the reflection layer 32 can be suppressed. As a result, stress occurring with thermal expansion and contraction acting on the boundary between the reflection layer 32 and the intermediate layer 13 is reduced, thereby exhibiting the effect of preventing the reflection layer 32 from delaminating from the intermediate layer 13, which is an under layer.

A similar effect is more noticeably achieved in the case of the light-emitting device 4A in which the reflection layer 32 is covered by the sealing resin 16, as in FIG. 12. In a case where the coefficient of linear expansion of the sealing resin 16 is equal to or larger than that of the reflection layer 32, the reflection layer 32 receives the effect of the expansion and contraction of the sealing resin 16 and thus tends to receive stress. However, when the mesh-woven glass sheet 31 with glass, which has a coefficient of linear expansion smaller than that of resin used in the sealing resin 16, as the raw material is used as the structural member within the reflection layer 32, stress occurring with thermal expansion and contraction acting on the boundary between the reflection layer 32 and the intermediate layer 13 is reduced in accordance with the above-described reason, thereby exhibiting the effect of preventing the reflection layer 32 pulled by the sealing resin 16 from delaminating from the intermediate layer 13, which is an under layer.

As described above in the specific example, the mechanism by which delamination can be reduced by using the mesh-woven glass sheet 31 as the structural member within the reflection layer 32 is summarized into two following points: (1) the thermal expansion and contraction of the reflection layer 32 can be localized at small divisions (mesh loops) forming the mesh structure of the glass sheet 31 and (2) the coefficient of linear expansion of the reflection layer 32 is pulled toward the coefficient of linear expansion of the glass sheet 31 so as to become closer to the coefficient of linear expansion of the intermediate layer 13. Consequently, thermal stress acting on the boundary between the reflection layer 32 and the intermediate layer 13 is reduced.

By using the structural member formed of the mesh-woven glass sheet 31 within the reflection layer 32, the substrate 10A according to the second embodiment has overcome the problem of delamination of the reflection layer having high light reflectivity and has successfully achieved long-term reliability for the first time, thereby realizing an ideal light-emitting-device substrate that simultaneously satisfies three conditions, namely, high light reflectivity, low thermal resistance (high heat dissipation), and high dielectric strength, which are required as the substrate 10A for the light-emitting device 4A that performs high-intensity illumination.

It is clear from the above description that, in the substrate 10A according to the second embodiment, the intermediate layer 13 formed of a ceramic layer is provided between the base 12 and the reflection layer 32, and the electrode pattern 14 is formed on the insulation layer formed of the intermediate layer 13 and the reflection layer 32. In this case, the mesh-woven glass sheet 31 is used as the structural member within the reflection layer 32. As a result, a substrate 10 for a light-emitting device 4A suitable for high-intensity illumination and having long-term reliability, particularly, long-term reliability of the reflection layer 32, in addition to high reflectivity, high heat dissipation, and high dielectric strength is achieved. With the substrate 10A according to the second embodiment, such a light-emitting-device substrate can be provided in a highly mass productive manner. The light-emitting device 4A or the illuminating apparatus 1 using this substrate 10A is highly mass productive and can realize long-term-reliable high-intensity illumination.

Although the outline of the substrate 10 in the second embodiment is rectangular when viewed in a direction orthogonal to the base surface direction, as shown in FIG. 12, the outline of the substrate 10 is not limited to this shape, and a freely-chosen closed shape may be employed. Moreover, the perimeter of the closed shape may be constituted of straight lines alone or a curve alone, or may include at least one straight line and at least one curve. Furthermore, the closed shape is not limited to a convex shape and may alternatively be a concave shape. For example, a triangular shape, a rectangular shape, a pentagonal shape, or an octagonal shape may be employed as an example of a convex polygonal shape constituted of straight lines alone, or a freely-chosen concave polygonal shape may be employed. Moreover, as an example of a closed shape constituted of a curve alone, a circular shape or an elliptical shape may be employed, or a closed shape such as a convex curve shape or a concave curve shape may be employed. Furthermore, as an example of a closed shape including at least one straight line and at least one curve, a racetrack-like shape may be employed.

### COMPARATIVE EXAMPLE

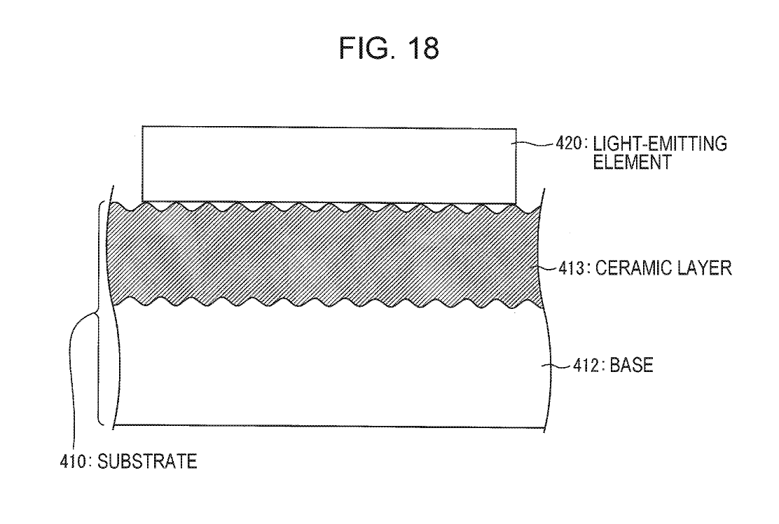

A comparative example with respect to the second embodiment will be described below with reference to FIG. 18. FIG. 18 is a cross-sectional view of a substrate 410 according to the comparative example with respect to the substrate 10A according to the second embodiment. FIG. 18 illustrates a partially enlarged view of a section of the substrate 410 on which a light-emitting element 420 is mounted. The substrate 410 has light-emitting elements 420 mounted on the surface thereof and includes a ceramic layer 413 disposed as an upper layer and an aluminum base 412 disposed as an under layer of the ceramic layer 413. Similar to the intermediate layer 13 in the second embodiment, the ceramic layer 413 is formed by plasma spraying.

When a ceramic layer is formed on a metallic base by spraying, the surface thereof often becomes irregular. This is mainly due to the particle size of material particles used in the spraying being relatively large from 10 μm to 50 μm.

Furthermore, as shown in FIG. 18, in a case where the ceramic layer 413 is to be laminated on the base 412 by spraying after giving the base 412 an irregular surface by blasting for the purpose of enhancing the adhesiveness between the base 412 and the ceramic layer 413, the effect of the irregular shape of the base 412 formed as a result of the blasting process remains on the surface of the laminated ceramic layer 413. The protrusions and recesses ultimately remaining on the surface of the ceramic layer 413 are substantially between 20 μm and 40 μm or even larger.

It is clear from FIG. 18 that the light-emitting elements 420 directly mounted on the surface having such large protrusions and recesses may result in insufficient contact between the light-emitting elements 420 and the ceramic layer 413 on which the light-emitting elements 420 are mounted, thus possibly causing the light-emitting elements 420 and the ceramic layer 413 to have high thermal resistance.

In contrast, in the two-layer structure including the intermediate layer 13 and the insulation layer 30 formed on the base 12 provided in the substrate 10A (see FIG. 13(c) according to the second embodiment, the irregular surface formed in the intermediate layer 13 is planarized by using the coating containing the reflector used for forming the reflection layer 32 of the insulation layer 30, so that the insulation layer 30 ultimately has a flat surface. Therefore, unlike the substrate 410 according to the comparative example shown in FIG. 18, the light-emitting elements 20 directly mounted on the insulation layer 30 in FIG. 13(c) can ensure sufficient contact with the insulation layer 30, so that the light-emitting elements 20 and the intermediate layer 13 can ensure sufficient heat dissipation and have low thermal resistance.

### Third Embodiment

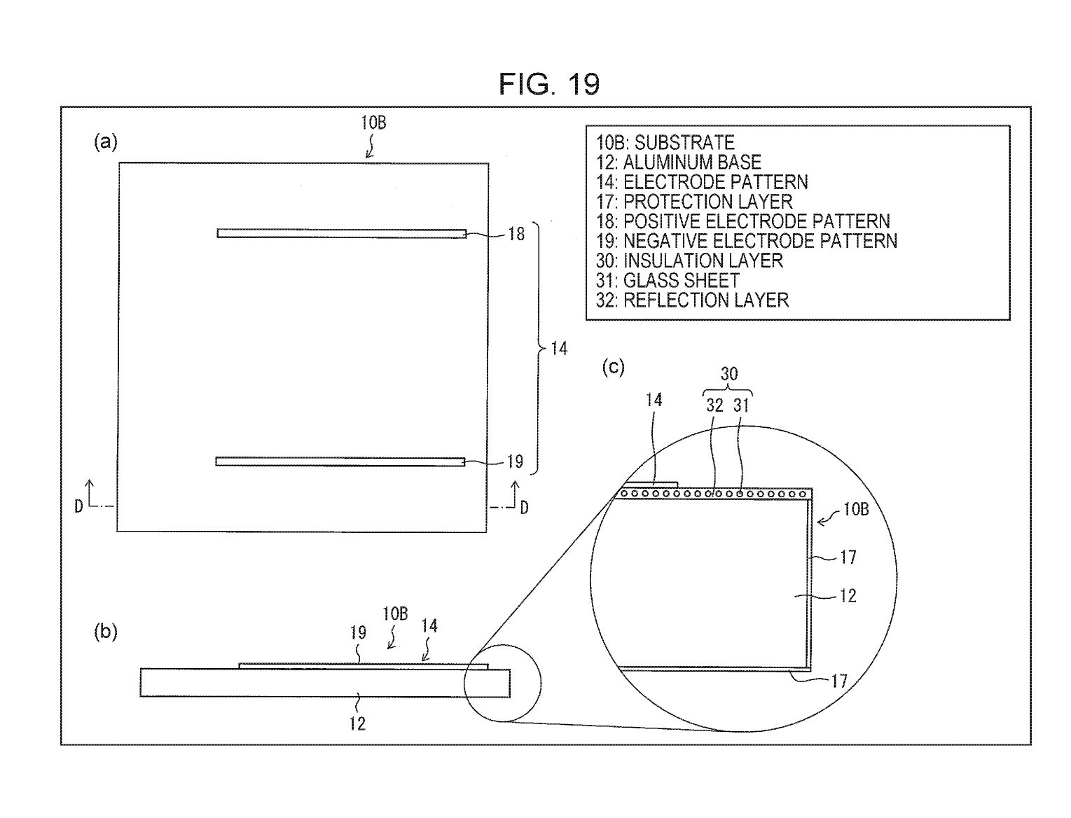

A third embodiment of the present invention will be described below with reference to FIG. 19. For the sake of convenience, components having functions identical to those of the components described in the first and second embodiments are given the same reference signs, and descriptions thereof will be omitted.

FIG. 19 includes a plan view (a) illustrating the configuration of a substrate 10B according to the third embodiment, a cross-sectional view (b) taken along a plane DD shown in (a), and a partially enlarged view (c) of the cross-sectional view. Similar to the substrate 10A according to the second embodiment, the substrate 10B according to the third embodiment is applicable to the light-emitting device 4A in FIG. 12 and to the illuminating apparatus 1 in FIG. 3.

In the second embodiment described above, the intermediate layer 13, the insulation layer 30, and the protection layer 17 are formed on the base 12. In contrast, in the substrate 10B according to the third embodiment, the insulation layer 30 and the protection layer 17 are formed on the base 12. The insulation layer 30 is formed on the surface (upper surface) (see FIG. 19(c)) of the base 12. The substrate 10B has a configuration in which the intermediate layer 13 is removed from the substrate 10A according to the second embodiment.

With the above-described configuration, the insulation and the thermal conductivity of the insulation layer 30 can be enhanced, so that a light-emitting-device substrate suitable for high-intensity illumination can be provided. By using the structural member formed of the mesh-woven glass sheet 31 within the reflection layer 32, the substrate 10B according to the third embodiment prevents delamination of the reflection layer having high light reflectivity and successfully achieves long-term reliability while being a light-emitting-device substrate that has high light reflectivity and low thermal resistance (high heat dissipation), which are required as a light-emitting-device substrate for high-intensity illumination.

[Conclusion]

A substrate 10, 10A, 10B, 310 according to aspect 1 of the present invention is a substrate 10, 10A, 10B, 310 for mounting a light-emitting element 20, 320 thereon and includes a base 12, 312 and a first insulation layer (insulation layer 30, 330) disposed directly or indirectly on a surface of the base 12, 312. The first insulation layer (insulation layer 30, 330) includes a resin layer (reflection layer 32, 332) that reflects light and a mesh structural member (glass sheet 31, 331) that is disposed within the resin layer (reflection layer 32, 332) and that has a coefficient of linear expansion smaller than that of the resin layer (reflection layer 32, 332).

According to the above configuration, because the first insulation layer has the mesh structural member having a coefficient of linear expansion smaller than that of the resin layer, the first insulation layer can be prevented from delaminating. Accordingly, dielectric strength and light reflectivity can be achieved, and reduction of the yield rate can be prevented, thereby providing a highly-mass-productive substrate for disposing a light-emitting element thereon.

A light-emitting device 4, 4A, 304 according to aspect 11 of the present invention includes a substrate 10, 10A, 10B, 310, a light-emitting element 20, 320 mounted on the substrate 10, 10A, 10B, 310, and sealing resin 16, 316 that covers the light-emitting element 20, 320. The substrate 10, 10A, 10B, 310 includes a base 12, 312 and a first insulation layer (insulation layer 30, 330) disposed directly or indirectly on a surface of the base 12, 312. The first insulation layer (insulation layer 30, 330) includes a resin layer (reflection layer 32, 332) that reflects light and a mesh structural member (glass sheet 31, 331) that is disposed within the resin layer (reflection layer 32, 332) and that has a coefficient of linear expansion smaller than that of the sealing resin 16, 316.

According to the above configuration, because the first insulation layer has the mesh structural member having a coefficient of linear expansion smaller than that of the sealing resin, the first insulation layer pulled by the sealing resin can be prevented from delaminating from the under layer. Accordingly, a light-emitting device having dielectric strength and light reflectivity as well as excellent long-term reliability can be provided.

In a substrate 10, 10A, 10B according to aspect 2 of the present invention, the structural member (glass sheet 31) is preferably composed of a glass material and the base 12 is preferably composed of a metallic material in aspect 1 above. In a light-emitting device 4, 4A, 304 according to aspect 12 of the present invention, the structural member (glass sheet 31, 331) is preferably composed of a glass material and the base 12, 312 is preferably composed of a metallic material in aspect 11 above.

According to the above configuration, since thermal expansion and contraction of the structural member are smaller than those of the resin layer, the first insulation layer can be prevented from delaminating.

In a substrate 10, 10A, 10B according to aspect 3 of the present invention, the structural member may be composed of polyether ether ketone resin or aromatic polyamide fiber, and the base 12, 312 may be composed of a metallic material in aspect 1 above. In a light-emitting device according to aspect 13 of the present invention, the structural member may be composed of polyether ether ketone resin or aromatic polyamide fiber, and the base 12, 312 may be composed of a metallic material in aspect 11 above.

According to this configuration, a mesh structural member having a coefficient of linear expansion smaller than that of the resin layer can be obtained. Furthermore, because the polyether ether ketone resin or the aromatic polyamide fiber has high heat resisting properties and high strength, a structural member having high heat resisting properties and high strength can be obtained.

In a substrate 10, 10A according to aspect 4 of the present invention, it is preferable that a second insulation layer (intermediate layer 13, alumina layer 313B and planarization layer 313C) be disposed between the base 12, 312 and the first insulation layer (insulation layer 30, 330) in aspects 1 to 3 above. In a light-emitting device 4, 4A, 304 according to aspect 14 of the present invention, it is preferable that a second insulation layer (intermediate layer 13, alumina layer 313B and planarization layer 313C) be disposed between the base 12, 312 and the first insulation layer (insulation layer 30, 330) in aspects 11 to 13 above. With the above configuration, high dielectric strength can be achieved.

In a substrate 10, 10A according to aspect 5 of the present invention, it is preferable that an electrode pattern 14, 314 be disposed on the second insulation layer (intermediate layer 13, alumina layer 313B and planarization layer 313C) in aspect 4 above. Moreover, the electrode pattern 14, 314 is preferably formed of a plurality of electrode terminals 14a and a wiring section 14b that connects between the electrode terminals 14a, and the first insulation layer (insulation layer 30, 330) preferably covers the wiring section 14b such that the plurality of electrode terminals 14a are exposed. In a light-emitting device 4, 4A, 304 according to aspect 15 of the present invention, it is preferable that an electrode pattern 14 be disposed on the second insulation layer (intermediate layer 13, alumina layer 313B and planarization layer 313C) in aspect 14 above. Moreover, the electrode pattern 14 is preferably formed of a plurality of electrode terminals 14a and a wiring section 14b that connects between the electrode terminals 14a, and the first insulation layer (insulation layer 30, 330) preferably covers the wiring section 14b such that the plurality of electrode terminals 14a are exposed. With the above configuration, the light-emitting element can be disposed so as to be electrically connected to the electrode terminals.

In a substrate 10, 10A according to aspect 6 of the present invention, the second insulation layer (intermediate layer 13, alumina layer 313B and planarization layer 313C) preferably has higher thermal conductivity than the first insulation layer (insulation layer 30, 330), and the first insulation layer (insulation layer 30, 330) preferably has higher light reflectivity than the second insulation layer (intermediate layer 13, alumina layer 313B and planarization layer 313C) in aspect 4 or 5 above. In a light-emitting device according to aspect 16 of the present invention, the second insulation layer (intermediate layer 13, alumina layer 313B and planarization layer 313C) preferably has higher thermal conductivity than the first insulation layer (insulation layer 30, 330), and the first insulation layer (insulation layer 30, 330) preferably has higher light reflectivity than the second insulation layer (intermediate layer 13, alumina layer 313B and planarization layer 313C) in aspect 14 or 15 above. With the above configuration, a substrate having high heat dissipation and high light reflectivity can be obtained.

In a substrate 10, 10A, 10B according to aspect 7 of the present invention, it is preferable that the resin layer (reflection layer 32, 332) be white and be composed of resin containing ceramic particles in aspect 1 to 6 above. In a light-emitting device 4, 4A, 304 according to aspect 17 of the present invention, it is preferable that the resin layer (reflection layer 32, 332) be white and be composed of resin containing ceramic particles. With the above configuration, high light reflectivity can be achieved.

In a substrate 10, 10A, 10B according to aspect 8 of the present invention, it is preferable that the ceramic particles include at least one of alumina, titanium oxide, silica, and zirconia in aspect 7 above. In a light-emitting device 4, 4A, 304 according to aspect 18 of the present invention, it is preferable that the ceramic particles include at least one of alumina, titanium oxide, silica, and zirconia in aspect 7 above. With the above configuration, the resin layer can be obtained.

In a substrate 10, 10A, 10B according to aspect 9 of the present invention, it is preferable that the resin include at least one of silicone resin, epoxy resin, fluorine resin, and polyimide resin in aspect 7 or 8 above. In a light-emitting device 4, 4A, 304 according to aspect 19 of the present invention, it is preferable that the resin include at least one of silicone resin, epoxy resin, fluorine resin, and polyimide resin in aspect 17 or 18 above.

In a light-emitting device 4, 4A, 304 according to aspect 10 of the present invention, it is preferable that a light-emitting element 20 be disposed on the substrate 10, 10A, 10B in aspect 1 to 9 above. With this configuration, a highly-mass-productive light-emitting device can be obtained.

The present invention is not limited to the embodiments described above, and various modifications are possible within the scope defined in the claims. An embodiment obtained by appropriately combining technical means disclosed in different embodiments is also included in the technical scope of the present invention. Furthermore, a new technical feature can be created by combining technical means disclosed in the embodiments.

### INDUSTRIAL APPLICABILITY

A substrate for mounting a light-emitting element thereon according to the present invention can be used as a substrate for various types of light-emitting devices. A light-emitting device according to the present invention can be particularly used as a high-intensity LED light-emitting device.

### REFERENCE SIGNS LIST

1 illuminating apparatus

4, 4A, 304 light-emitting device

10, 10A, 10B, 310 substrate

12, 312 base

13 intermediate layer (second insulation layer)

14, 314 electrode pattern

14a electrode terminal

14b wiring section

16, 316 sealing resin

17 protection layer

18 positive electrode pattern

19 negative electrode pattern

20, 320 light-emitting element

30, 330 insulation layer (first insulation layer)

31, 331 glass sheet (structural member)

32, 332 reflection layer (resin layer)

32a light reflective coating

313B alumina layer (second insulation layer)

313C planarization layer (second insulation layer)

1-5. (canceled)

6. A substrate for mounting a light-emitting element thereon, comprising:
a base;
a first insulation layer disposed indirectly on a surface of the base;
a second insulation layer disposed between the base and the first insulation layer; and
an electrode pattern disposed on the second insulation layer,
wherein the first insulation layer includes a resin layer that reflects light and a mesh structural member that is disposed within the resin layer and that has a coefficient of linear expansion smaller than that of the resin layer,
wherein the electrode pattern includes a plurality of electrode terminals and a wiring section that connects between the electrode terminals, and
wherein the first insulation layer covers the wiring section such that the plurality of electrode terminals are exposed.

7. The substrate according to claim 6,
wherein the structural member is composed of a glass material, and
wherein the base is composed of a metallic material.

8. The substrate according to claim 6,
wherein the structural member is composed of polyether ether ketone resin or aromatic polyamide fiber, and
wherein the base is composed of a metallic material.

9. The substrate according to claim 6,
wherein the second insulation layer has higher thermal conductivity than the first insulation layer, and
wherein the first insulation layer has higher light reflectivity than the second insulation layer.

10. The substrate according to claim 6,
wherein the resin layer is white and is composed of resin containing ceramic particles.

11. The substrate according to claim 10,
the ceramic particles include at least one of alumina, titanium oxide, silica, and zirconia.

12. The substrate according to claim 10,
wherein the resin includes at least one of silicone resin, epoxy resin, fluorine resin, and polyimide resin.

13. A light-emitting device comprising:
a substrate;
a light-emitting element mounted on the substrate; and
sealing resin that covers the light-emitting element,
wherein the substrate includes:
a base;
a first insulation layer disposed indirectly on a surface of the base;
a second insulation layer disposed between the base and the first insulation layer; and
an electrode pattern disposed on the second insulation layer,
wherein the first insulation layer includes a resin layer that reflects light and a mesh structural member that is disposed within the resin layer and that has a coefficient of linear expansion smaller than that of the sealing resin,
wherein the electrode pattern includes a plurality of electrode terminals and a wiring section that connects between the electrode terminals, and
wherein the first insulation layer covers the wiring section such that the plurality of electrode terminals are exposed.

14. The light-emitting device according to claim 13,
wherein the structural member is composed of a glass material, and
wherein the base is composed of a metallic material.

15. The light-emitting device according to claim 13,
wherein the structural member is composed of polyether ether ketone resin or aromatic polyamide fiber, and
wherein the base is composed of a metallic material.

16. The light-emitting device according to claim 13,
wherein the second insulation layer has higher thermal conductivity than the first insulation layer, and
wherein the first insulation layer has higher light reflectivity than the second insulation layer.

17. The light-emitting device according to claim 13,
wherein the resin layer is white and is composed of resin containing ceramic particles.

18. The light-emitting device according to claim 17,
the ceramic particles include at least one of alumina, titanium oxide, silica, and zirconia.

19. The light-emitting device according to claim 17,
wherein the resin includes at least one of silicone resin, epoxy resin, fluorine resin, and polyimide resin.

20. A illuminating apparatus comprising a light-emitting device recited in claim 13.
